(19) United States
(12) Patent Application Publication
(10) Pub. No.: US 2026/0189207 A1
(43) Pub. Date: Jul. 2, 2026

(54) IMPEDANCE MATCHER

(71) Applicant: DAIHEN Corporation, Osaka (JP)

(72) Inventors: Takushi MORISHIMA, Osaka (JP); Toshio MINAMI, Osaka (JP)

(21) Appl. No.: 19/417,893

(22) Filed: Dec. 12, 2025

(30) Foreign Application Priority Data
Dec. 26, 2024 (JP) 2024-230127

(51) Int. Cl. H03H 7/40; H01J 37/32

(52) U.S. Cl. CPC H03H 7/40; H01J 37/32146; H01J 37/32183; H01J 37/32155; H01J 2237/327

(57) ABSTRACT

An impedance matcher includes: a matcher-dedicated setting value information output circuit configured to output a matcher-dedicated setting value corresponding to an elapsed time from a start point of a cycle within a time of one cycle of amplitude modulation of a high-frequency power source or a command signal corresponding to the matcher-dedicated setting value; and a control circuit configured to output a control signal to the matching circuit based on the matcher-dedicated setting value or the command signal. The matcher-dedicated setting value information output circuit is configured to set, as the start point, a time point at which a cycle start signal that is a signal generated for each time of one cycle of the amplitude modulation and is common to the high-frequency power source is input or a time point obtained by adding a delay time to the time point at which the cycle start signal is input.

### CROSS-REFERENCE TO RELATED APPLICATIONS

This application is based upon and claims the benefit of priority from Japanese Patent Application No. 2024-230127, filed on December 26, 2024, the entire contents of which are incorporated herein by reference.

### FIELD

The present disclosure relates to an impedance matcher.

### BACKGROUND

For example, a high-frequency power supply system used in a plasma treatment apparatus includes two high-frequency power source devices (a first high-frequency power source and a second high-frequency power source) and outputs high-frequency voltages (forward wave voltages) having different fundamental frequencies (frequencies of fundamental waves) from the individual power sources toward a load. For example, the first high-frequency power source supplies high-frequency power (first forward wave power) to the load by outputting a high-frequency voltage (a forward wave voltage VF1) having a fundamental frequency F1 suitable for plasma generation. The second high-frequency power source supplies high-frequency power (second forward wave power) to the load by outputting a high-frequency voltage (a forward wave voltage VF2) having a fundamental frequency F2 (the fundamental frequency F1 > the fundamental frequency F2) suitable for ion acceleration (see Japanese Unexamined Patent Application, Publication No. 2024-95370).

In addition, a first impedance matcher (hereinafter, a first matcher) is provided between the first

high-frequency power source and the load and performs impedance matching by adjusting a value of an internal variable element (for example, a capacitance value of a variable capacitor) such that a power value of reflected wave power at an output end of the first high-frequency power source (an input end of the first impedance matcher) decreases. In addition, a second impedance matcher (hereinafter, a second matcher) is provided between the second high-frequency power source and the load and performs impedance matching by adjusting a value of an internal variable element (for example, a capacitance value of a variable capacitor) such that a power value of reflected wave power at an output end of the second high-frequency power source (an input end of the second impedance matcher) decreases. Note that the matcher may be referred to as a matching box.

In a high-frequency power source device such as a first high-frequency power source or a second high-frequency power source, two-stage amplitude modulation may be performed, in which ON operation of outputting a high-frequency voltage (high-frequency power) and OFF operation of not outputting a high-frequency voltage (high-frequency power) are repeated. In addition, two-stage amplitude modulation may be performed, in which a first level and a second level are repeated, instead of the ON operation and the OFF operation. Further, various output controls such as gradual decrease or gradual increase of an output level and gradual decrease or gradual increase of a duty ratio are performed (see Japanese Unexamined Patent Application, Publication No. 2021-57929).

In impedance matchers, in order to accurately perform impedance matching, for example, load information in a period during which a predetermined power value or larger is measured is acquired, and matching operation is performed based on the acquired load information.

Here, in the high-frequency power supply system as described above, in a case where the high-frequency power source device performs the amplitude modulation, a cycle start signal (corresponding to a synchronizing pulse signal of Japanese Unexamined Patent Application, Publication No. 2024-95370) can be transmitted from the outside to individual devices (the high-frequency power source device and the impedance matcher). This enables the impedance matcher to recognize a start point of a cycle within a time of one cycle of the amplitude modulation.

As in Japanese Unexamined Patent Application, Publication No. 2024-95370, if it is assumed that the high-frequency power source device repeats the ON operation and the OFF operation, a power source-ON period and a power source-OFF period can be identified by cycle start signals input from the outside. Therefore, the impedance matcher may acquire the load information in a period during a predetermined period of the power source-ON period. For example, the load information may be acquired in a period after a predetermined time elapses after the power source-ON period starts until the power source-ON period ends.

However, as in Japanese Unexamined Patent Application, Publication No. 2021-57929, in a case where the high-frequency power source device performs a complicated amplitude modulation control such as gradual decrease or increase of the output level or gradual decrease or increase of the duty ratio, a period during which the load information is to be acquired cannot be identified only by the cycle start signal.

Therefore, it is conceivable that the high-frequency power source device outputs, to the impedance matcher, an acquisition timing signal for identifying a period during which the load information is to be acquired.

Such an acquisition timing signal needs to be output from the high-frequency power source device to the

impedance matcher in accordance with a target power value of the high-frequency power source device, but there is a possibility that the acquisition timing signal cannot be output from the high-frequency power source device to the impedance matcher at an appropriate timing depending on a communication status between the high-frequency power source device and an external control device in the high-frequency power source device.

The present disclosure provides an impedance matcher that can make it unnecessary to output an acquisition timing signal of load information from a high-frequency power source to the impedance matcher.

### SUMMARY

An impedance matcher according to the present disclosure includes an input end, an output end, a matching circuit, a matcher-dedicated setting value information output circuit, and a control circuit. The input end is connectable to a high-frequency power source configured to supply high-frequency power. The output end is connectable to a load. The matching circuit that includes a variable element inside and is capable of changing impedance when viewed from the input end. The matcher-dedicated setting value information output circuit is configured to output a matcher-dedicated setting value corresponding to an elapsed time from a start point of a cycle within a time of one cycle of amplitude modulation in a case where the high-frequency power source performs amplitude modulation control or a command signal corresponding to the matcher-dedicated setting value based on matcher-dedicated setting value information indicating a relationship between the elapsed time and the matcher-dedicated setting value. The control circuit is configured to output a control signal to the matching circuit based on the matcher-dedicated setting value or the command signal output from the matcher-dedicated setting value information

output circuit. The matcher-dedicated setting value information output circuit is configured to set, as the start point, a time point at which a cycle start signal that is a signal generated for each time of one cycle of the amplitude modulation and is common to the high-frequency power source is input or a time point obtained by adding a delay time to the time point at which the cycle start signal is input.

### BRIEF DESCRIPTION OF THE DRAWINGS

FIG. 1 is a diagram illustrating a configuration of a high-frequency power supply system according to an embodiment;

FIGS. 2A to 2E are graphs for describing an example of an amplitude modulation waveform, an acquisition period of load information, and a cycle start signal in the embodiment;

FIGS. 3A to 3D are tables for describing a setting example of setting value information in the embodiment;

FIGS. 4A to 4D are tables for describing another setting example of the setting value information in the embodiment;

FIGS. 5A to 5D are tables for describing still another setting example of the setting value information in the embodiment;

FIGS. 6A to 6D are tables for describing still another setting example of the setting value information in the embodiment;

FIGS. 7A to 7E are graphs for describing another example of the amplitude modulation waveform, the acquisition period of load information, and the cycle start signal in the embodiment;

FIGS. 8A to 8D are tables for describing another setting example of the setting value information in the embodiment;

FIG. 9 is a graph illustrating another example of the amplitude modulation waveform of a first high-frequency power source in the embodiment;

FIG. 10 is a table illustrating an example of first high-frequency power source-dedicated setting value information corresponding to FIG. 9 in the embodiment; and

FIG. 11 is a diagram illustrating a configuration of a high-frequency power supply system according to a modification example of the embodiment.

### DETAILED DESCRIPTION

Hereinafter, an embodiment of a high-frequency power supply system according to the present disclosure will be described with reference to the drawings.

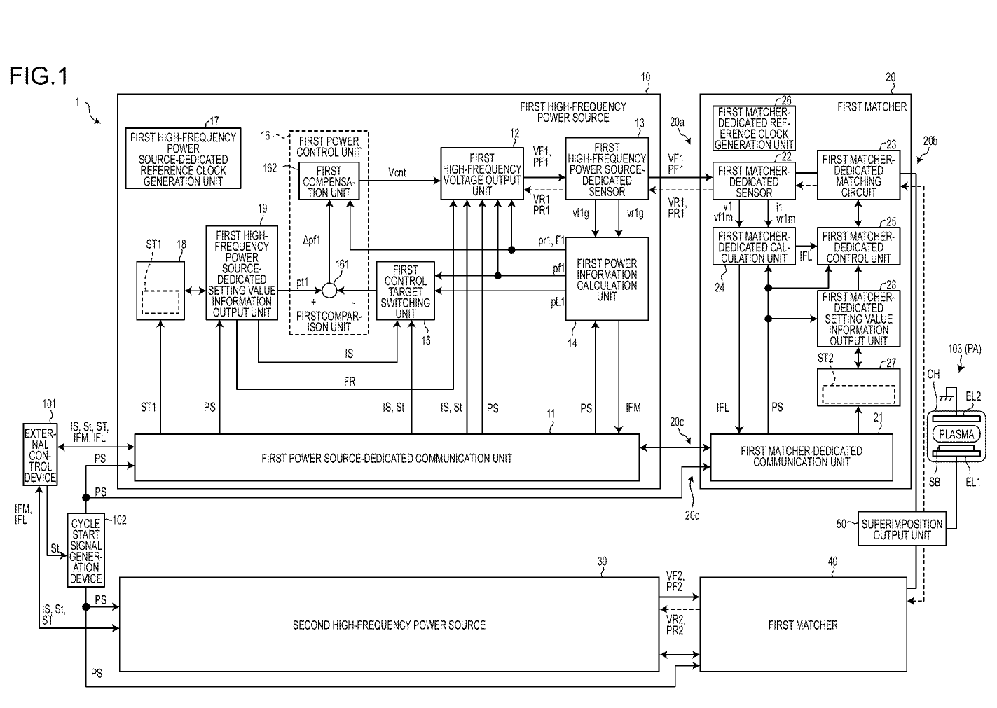

FIG. 1 is a diagram illustrating a configuration of a high-frequency power supply system 1.

The high-frequency power supply system 1 is a device that supplies high-frequency power to a load 103 (for example, a plasma treatment apparatus PA) by outputting a high-frequency voltage having a fundamental frequency (a frequency of a fundamental wave) of an RF band (RF: radio frequency) from a high-frequency power source device. The high-frequency power supply system 1 includes, for example, a first high-frequency power source device (hereinafter referred to as a first high-frequency power source) 10, a second high-frequency power source device (hereinafter referred to as a second high-frequency power source) 30, a first impedance matcher (hereinafter referred to as a first matcher) 20, a second impedance matcher (hereinafter referred to as a second matcher) 40, and a superimposition output unit (outputter) 50.

Also, the first high-frequency power source 10 outputs a high-frequency voltage toward the load 103 via the first matcher 20. In addition, the second high-frequency power source 30 outputs a high-frequency voltage having the same or different fundamental frequency as or from that of the first high-frequency power source 10 toward the load 103 via the second matcher 40.

In addition, in this specification, the fundamental

frequency of the first high-frequency power source 10 is set as a fundamental frequency F1 (an example of a first fundamental frequency), and the fundamental frequency of the second high-frequency power source 30 is set as a fundamental frequency F2 (an example of a second fundamental frequency).

Note that the high-frequency power supply system 1 may not include the second high-frequency power source 30, the second matcher 40, and the superimposition output unit 50 described above. Namely, the high-frequency power supply system 1 may include the single first high-frequency power source 10 as the high-frequency power supply and the single first matcher 20 as the matcher, and only the high-frequency voltage (high-frequency power) output from the first high-frequency power source 10 may be supplied to the load 103 via the first matcher 20. As a matter of course, it is also possible to use a matcher corresponding to three or more high-frequency power source devices.

In addition to the high-frequency power source devices 10 and 30, a DC power source device that supplies a DC voltage to the load 103 may be provided, although omitted in the embodiment.

In addition, the high-frequency voltage output from the first high-frequency power source 10 toward the load 103 is referred to as a forward wave voltage VF1, a high-frequency voltage which is reflected from the load 103 side and returns to the first high-frequency power source 10 is referred to as a reflected wave voltage VR1, the high-frequency power output from the first high-frequency power source 10 toward the load 103 is referred to as forward wave power PF1, and high-frequency power which is reflected from the load 103 side and returns to the first high-frequency power source 10 is referred to as reflected wave power PR1.

In addition, the high-frequency voltage output from the second high-frequency power source 30 toward the load 103 is referred to as a forward wave voltage VF2, high-frequency voltage which is reflected from the load 103 side and returns to the second high-frequency power source 30 is referred to as a reflected wave voltage VR2, the high-frequency power output from the second high-frequency power source 30 toward the load 103 is referred to as forward wave power PF2, and high-frequency power which is reflected from the load 103 side and returns to the second high-frequency power source 30 is referred to as reflected wave power PR2.

In addition, a power value of the forward wave power PF1 is referred to as a forward wave power value pf1, a power value of the reflected wave power PR1 is referred to as a reflected wave power value pr1, a power value obtained by subtracting the reflected wave power value pr1 from the forward wave power value pf1 is referred to as a load-side power value pL1, a power value of the forward wave power PF2 is referred to as a forward wave power value pf2, a power value of the reflected wave power PR2 is referred to as a reflected wave power value pr2, and a power value obtained by subtracting the reflected wave power value pr2 from the forward wave power value pf2 is referred to as a load-side power value pL2.

In addition, in this specification, a reflection coefficient represented by a ratio of a reflected wave voltage to a forward wave voltage (reflected wave voltage/forward wave voltage) is denoted by ρ, and an absolute value (a magnitude) of the reflection coefficient ρ is denoted by Γ. Therefore, a reflection coefficient on the first high-frequency power source 10 side is referred to as a reflection coefficient ρ1, a reflection coefficient on the second high-frequency power source 30 side is referred to as a reflection coefficient ρ2, a reflection coefficient absolute value on the first high-frequency power source 10 side is referred to as a reflection coefficient absolute value Γ1, and a reflection coefficient absolute value on the second high-frequency power source 30 side is referred to as a reflection coefficient absolute value Γ2.

In addition, indexes are used as necessary to indicate corresponding positions. For example, "1" is used for a system of the first high-frequency power source 10 and the first matcher 20, "2" is used for a system of the second high-frequency power source 30 and the second matcher 40, "g" is used for a system involving the first high-frequency power source 10 and the second high-frequency power source 30, and "m" is used for a system involving the first matcher 20 and the second matcher 40.

In addition, the high-frequency power source device such as the first high-frequency power source 10 or the second high-frequency power source 30 can decrease a power value of the reflected wave power by changing the frequency of the forward wave voltage to be output. Hereinafter, this function is referred to as "frequency matching". When the frequency matching is performed, the fundamental frequency of the forward wave voltage is not constant but fluctuates, and the term the fundamental frequency (in the example described above, the fundamental frequency F1 and the fundamental frequency F2) is used including a case where such a fundamental frequency fluctuates.

In addition, the high-frequency power source device such as the first high-frequency power source 10 or the second high-frequency power source 30 may perform a frequency modulation control, for example, in order to decrease a power value of the reflected wave power due to intermodulation distortion (hereinafter IMD). Also in a case where the frequency modulation control is performed, the fundamental frequency of the forward wave voltage is not constant but fluctuates, and the term the fundamental frequency (in the example described above, the fundamental frequency F1 and the fundamental frequency F2) is used.

The first high-frequency power source 10 supplies the forward wave power PF1 to the load 103 by outputting the forward wave voltage VF1 having the fundamental frequency F1. At this time, a feedback control is performed such that an error between the forward wave power value pf1 and a target power value pt1 is decreased. Such a power control is referred to as a forward wave power constant control (a PF constant control).

Note that it is also possible to perform a feedback control such that an error between the load-side power value pL1 and the target power value pt1 is decreased. Such a power control is referred to as a load-side power constant control (a PL constant control). However, in the following description, a case where the forward wave power constant control is performed will be mainly described as an example.

The forward wave voltage VF1 has a relatively high fundamental frequency F1 suitable for plasma generation. The fundamental frequency F1 is, for example, 40.68 MHz. As a matter of course, the fundamental frequency F1 is not limited to 40.68 MHz and may be, for example, a frequency of the industrial RF band such as 13.56 MHz or 27.12 MHz.

The first high-frequency power source 10 can not only perform a continuous wave output in which the forward wave power value pf1 or the load-side power value pL1 is constant, but also change and output a target power value during a predetermined cycle. Since an amplitude of the forward wave voltage VF1 to be output is changed when the target power value is changed, such an output control is referred to as an amplitude modulation control in this specification. In addition, the output control is referred to as amplitude modulation for simple description. Note that the second high-frequency power source 30 can also perform the amplitude modulation control.

For example, two-stage amplitude modulation may be performed at a predetermined cycle, in which ON operation of outputting the forward wave power value pf1 and OFF operation of not outputting the forward wave power value pf1 are repeated. In addition, two-stage amplitude modulation in which a first level and a second level are repeated or multi-stage amplitude modulation of three or more levels may be performed, instead of the ON operation and the OFF operation.

Further, various output controls such as an output control of gradually decreasing or gradually increasing an output level, an output control of gradually decreasing or gradually increasing a duty ratio, a frequency modulation control of changing the fundamental frequency F1, and frequency matching can be performed.

The second high-frequency power source 30 supplies the forward wave power PF2 to the load 103 by outputting the forward wave voltage VF2 having the fundamental frequency F2. The fundamental frequency F2 is the same as or different from the fundamental frequency F1.

At this time, in the second high-frequency power source 30, the feedback control (the forward wave power constant control) is performed such that an error between the forward wave power value pf2 and the target power value pt2 is decreased. Similarly to the first high-frequency power source 10, the feedback control (the load-side power constant control) may be performed such that an error between the load-side power value pL2 and the target power value pt2 is decreased. However, in the following description, a case where the forward wave power constant control is performed will be mainly described as an example.

The forward wave voltage VF2 has, for example, a relatively low fundamental frequency F2 suitable for ion acceleration. The fundamental frequency F2 is, for example, 400 kHz. As a matter of course, the fundamental frequency F2 is not limited to 400 kHz and may be another frequency. For example, the fundamental frequency F2 may be a frequency of the industrial RF band such as 13.56 MHz or 27.12 MHz. In addition, the fundamental frequency F2 is not necessarily limited to a frequency lower than the fundamental frequency F1 and may be the same frequency as the fundamental frequency F1 or a frequency higher than the fundamental frequency F1.

Similarly to the first high-frequency power source 10, the second high-frequency power source 30 is configured to perform various output controls.

For example, the superimposition output unit 50 is electrically connected between the load 103 and the first high-frequency power source 10 and the second high-frequency power source 30.

The load 103 may be, for example, the plasma treatment apparatus PA. The plasma treatment apparatus PA is, for example, of a parallel plate type, and a lower electrode EL1 and an upper electrode EL2 face each other in a chamber CH. A substrate SB which is a processing target can be placed on the lower electrode EL1. The first high-frequency power source and the second high-frequency power source are electrically connected to the lower electrode EL1 via the superimposition output unit 50. The upper electrode EL2 is electrically connected to a ground potential. The chamber CH is connected to a gas supply device (not illustrated) via an air supply pipe and is connected to a vacuum device (not illustrated) via an exhaust pipe.

In a case where the load 103 is the plasma treatment apparatus PA, the superimposition output unit 50 may be electrically connected between the lower electrode EL1 of the plasma treatment apparatus PA and the first high-frequency power source 10 and the second high-frequency power source 30.

An external control device 101 is, for example, a device that sends various commands (such as an output start command of the forward wave voltage) IS or various setting values (such as the target power value) St to the high-frequency power supply system 1. In addition, for example, the external control device can be used for acquisition, analysis, or the like of information (monitor information) IFM such as the forward wave power value pf1 calculated by the first high-frequency power source 10. In addition, the external control device can send the various setting values St such as a time of one cycle of amplitude modulation to a cycle start signal generation device 102 to be described below. This enables the time of one cycle of amplitude modulation or the like to be changed.

Note that, in an example illustrated in FIG. 1, various commands IS and various setting values St output from the external control device 101 are transmitted to the first matcher 20 via a first high-frequency power source-dedicated communication unit 11 to be described below. In addition, the various commands IS and the various setting values St output from the external control device 101 are transmitted to the second matcher 40 via a first matcher-dedicated communication unit 21 to be described below. However, the various commands IS and the various setting values St may be directly transmitted from the external control device 101 to each of the first matcher 20 and the second matcher 40.

Note that the high-frequency power supply system 1 and the load 103 (for example, the plasma treatment apparatus PA) are not limited to the configuration of FIG. 1. For example, there are various configurations such as a configuration in which, without the superimposition output unit 50 that superimposes the forward wave voltage VF1 and the forward wave voltage VF2, the forward wave voltage VF1 output from the first high-frequency power source 10 is supplied to the upper electrode EL2 via the first matcher 20 (in this case, different from the configuration of FIG. 1, the upper electrode EL2 is not electrically connected to the ground potential), and the forward wave voltage VF2 output from the second high-frequency power source 30 is supplied to the lower electrode EL1 via the second matcher 40. The high-frequency power supply system of the embodiment can also be used for such other configurations.

The cycle start signal generation device 102 outputs a cycle start signal PS for each time of one cycle of amplitude modulation.

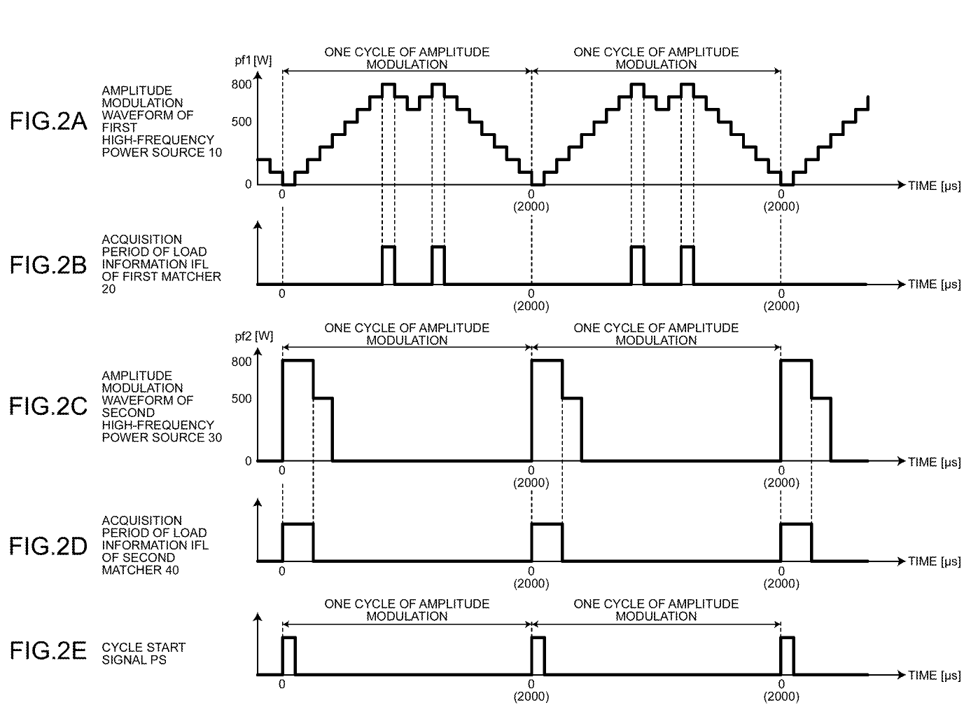

FIGS. 2A to 2E are graphs for describing an example of an amplitude modulation waveform, an acquisition period of load information IFL, and the cycle start signal PS. Note that, in the example of FIGS. 2A to 2E, a case where a time of one cycle of the amplitude modulation is 2,000 μs, and the amplitude modulation of the same waveform is repeated is illustrated.

Here, a time on the horizontal axis is an elapsed time from a start point of a cycle within the time of one cycle of the amplitude modulation. Hence, in a case where the amplitude modulation is repeated, the time on the horizontal axis is the time from the start point of the cycle within the time of one cycle of the amplitude modulation that newly starts. Namely, the time at the start point of the cycle is 0 (zero).

In addition, an acquisition period of the load information indicates a specific period during which information of the reflection coefficient ρ or a load-side impedance Z necessary for impedance matching in the impedance matchers (the first matcher 20 and the second matcher 40) is acquired.

FIG. 2A is an example of the amplitude modulation waveform of the first high-frequency power source 10 and illustrates that the forward wave power value pf1 changes with an elapsed time within the time of one cycle of the amplitude modulation. In this manner, the first high-frequency power source 10 can change output levels in multiple stages.

Note that, since the fundamental frequency F1 of the forward wave voltage VF1 in the embodiment is, for example, 40.68 MHz, an accurate waveform cannot be illustrated in the drawings. Therefore, in FIG. 2A, a waveform of the forward wave voltage VF1 is not illustrated, and a magnitude of the forward wave power value pf1 is illustrated. The same applies not only to FIG. 2A but also to the other drawings such as FIG. 2C.

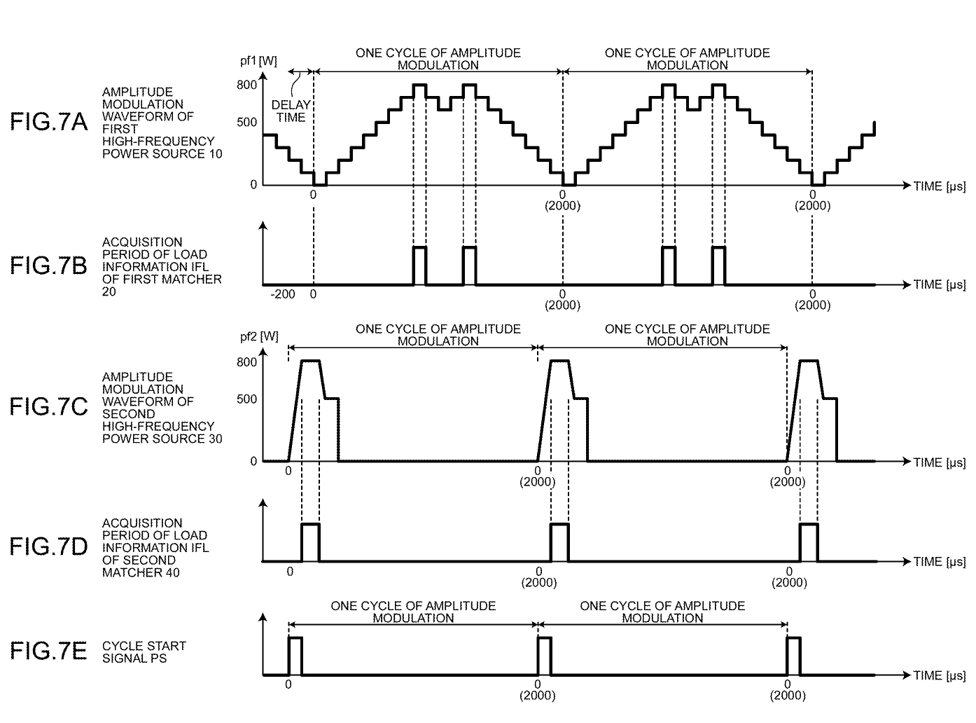

Note that the vertical axis in FIG. 2A may represent a magnitude of the load-side power value pL1, but in order to simplify the description, the vertical axis represents the magnitude of the forward wave power value pf1. The same applies to FIG. 7A to be described below.

FIG. 2B is an example of the acquisition period of the load information IFL (the reflection coefficient ρ or the load-side impedance Z) in the first matcher 20. Note that FIG. 2B illustrates a case where a period during which the highest target power value of the first high-frequency power source 10 is set is defined as a specific period, and the first matcher 20 acquires the load information IFL in this specific period.

The first matcher 20 may acquire the load information (the reflection coefficient ρ or the load-side impedance Z) IF in the whole period of one cycle of the amplitude modulation and perform matching operation using the acquired load information IFL, or may acquire the load information IFL in the specific period and perform the matching operation based on the acquired load information IFL. In this case, in the other periods, the matching operation may be performed by setting the same load information IFL as that in the specific period. As a matter of course, the specific period is not limited to the period during which the highest target power value of the first high-frequency power source 10 is set.

FIG. 2C is an example of the amplitude modulation waveform of the second high-frequency power source 30 and illustrates that the forward wave power value pf2 changes with the elapsed time within the time of one cycle of the amplitude modulation. In this manner, the second high-frequency power source 30 can change output levels in multiple stages.

Note that the vertical axis in FIG. 2C may represent a magnitude of the load-side power value pL2, but in order to simplify the description, the vertical axis represents the magnitude of the forward wave power value pf2. The same applies to FIG. 7C to be described below.

FIG. 2D is an example of the acquisition period of the load information IFL (the reflection coefficient ρ or the load-side impedance Z) in the second matcher 40. Note that FIG. 2D illustrates a case where a period during which the highest target power value of the second high-frequency power source 30 is set is defined as a specific period, and the second matcher 40 acquires the load information IFL in this specific period.

The second matcher 40 may acquire the load information (the reflection coefficient ρ or the load-side impedance Z) IFL in the whole period of one cycle of the amplitude modulation and perform matching operation using the acquired load information IFL, or may acquire the load information IFL in the specific period and perform the matching operation based on the acquired load information IFL. In this case, in the other periods, the matching operation may be performed by setting the same load information IFL as that in the specific period. As a matter of course, the specific period is not limited to the period during which the highest target power value of the first high-frequency power source 10 is set.

Note that the second matcher 40 may not acquire the load information IFL in the whole specific period. For example, since, immediately after the target power value of the first high-frequency power source 10 is changed, a state of the load 103 becomes unstable, the load information IFL may be acquired after a predetermined time elapses after the target power value of the first high-frequency power source 10 is changed.

In addition, it is not necessary to change a variable value of a variable element inside the first matcher-dedicated matching circuit 23 in the whole period. For example, immediately after the target power value of the first high-frequency power source 10 is changed, the variable value of the variable element may be maintained.

FIG. 2E illustrates an example of the cycle start signal PS and illustrates a signal in which a cycle time is set in accordance with the time of one period of amplitude modulation. As can be known from FIGS. 2A to 2E, a start point (a start time point) of a cycle of the amplitude modulation can be defined in response to the cycle start signal PS.

In the example of FIG. 2E, the cycle start signal PS is a pulse signal that changes from a low level to a high level at the start point of the cycle of the amplitude modulation, but a magnitude relationship before and after the change is not limited to the example illustrated in FIG. 2E. For example, the cycle start signal PS may be a pulse signal that changes from the high level to the low level. In addition, a signal transmitted by serial communication (for example, a bit pattern having a predetermined length) may be used instead of the pulse signal.

The use of the cycle start signal PS enables control timings such as output start timings of high-frequency voltages between received devices to be synchronized. Namely, the cycle start signal PS functions as a signal for controlling synchronization in the devices to which the cycle start signal PS is supplied.

For example, when the devices to be synchronized are the first high-frequency power source 10, the first matcher 20, the second high-frequency power source 30, and the second matcher 40, the cycle start signal PS may be supplied to these devices. As a matter of course, when the devices to be synchronized are the two devices of the first high-frequency power source 10 and the first matcher 20, the cycle start signal PS may be supplied to the first high-frequency power source 10 and the first matcher 20.

Note that the time of one cycle of the amplitude modulation is not fixed but can be changed. Therefore, the cycle start signal generation device 102 is configured to be capable of setting a time of one cycle necessary for generating the cycle start signal PS. For example, information of the time of one cycle may be output from the external control device 101, and the information may be stored in a storage unit (not illustrated) of the cycle start signal generation device 102. In addition, a generation timing of the cycle start signal PS may be adjustable. For example, the cycle start signal PS may be output when the command IS is issued from the external control device 101.

In addition, in the example of FIG. 1, the cycle start signal generation device 102 is arranged outside the first high-frequency power source 10, but may be disposed, for example, in another position such as an inside of the first high-frequency power source 10.

### Description of Outline Operation of High-Frequency Power Supply System 1

The forward wave voltage VF1 (the forward wave power value pf1) output from the first high-frequency power source 10 can be supplied to the lower electrode EL1 of the load 103 (for example, the plasma treatment apparatus PA) via the first matcher 20 and the superimposition output unit 50. The forward wave voltage VF2 (the forward wave power value pf2) output from the second high-frequency power source 30 can be supplied to the lower electrode EL1 of the plasma treatment apparatus PA via the second matcher 40 and the superimposition output unit 50.

Namely, in the embodiment, the forward wave voltage VF1 and the forward wave voltage VF2 are superimposed in the superimposition output unit 50 and are supplied to the lower electrode EL1. This allows the plasma treatment apparatus PA to generate plasma between the lower electrode EL1 and the upper electrode EL2. In addition, first matching operation of matching impedance on the first high-frequency power source 10 side with impedance on the load 103 side is executed in the first matcher 20, and second matching operation of matching impedance on the second high-frequency power source 30 side with impedance on the load 103 side is executed in the second matcher 40.

The first high-frequency power source 10 and the second high-frequency power source 30 control output power to have respective predetermined target power values. In a case where the first high-frequency power source 10 performs the amplitude modulation, the target power value is changed at a predetermined time point. Also in a case where the second high-frequency power source 30 performs the amplitude modulation, the target power value is changed at the predetermined time point.

Here, the predetermined time point corresponds to an elapsed time in a case where a time point of a start point of a cycle within the time of one cycle of the amplitude modulation is 0.

In the high-frequency power supply system 1, when an output pattern of the amplitude modulation becomes complicated, setting of the target power value or the like also becomes complicated, thus requiring a lot of labor. Therefore, in the embodiment, the target power value or the like is set based on setting value information ST to be described below, and labor for the setting is reduced.

Note that, in the embodiment, the setting value information ST used by the first high-frequency power source 10 is referred to as first high-frequency power source-dedicated setting value information ST1, the setting value information ST used by the first matcher 20 is referred to as first matcher-dedicated setting value information ST2, the setting value information ST used by the second high-frequency power source is referred to as second high-frequency power source-dedicated setting value information ST3, and the setting value information ST used by the second matcher 40 is referred to as second matcher-dedicated setting value information ST4.

Hereinafter, the first high-frequency power source 10 and the first matcher 20 will be described in detail, and then the setting value information ST and related matters will be described. Note that the second high-frequency power source 30 and the second matcher 40 have the same basic functions as those of the first high-frequency power source 10 and the first matcher 20, respectively, and thus, the description thereof is omitted.

### Details of First High-frequency Power Source 10

A configuration of the first high-frequency power source 10 will be described below with reference to FIG. 1.

The first high-frequency power source 10 includes the first high-frequency power source-dedicated communication unit 11, a first high-frequency voltage output unit 12, a first high-frequency power source-dedicated sensor 13, a first power information calculation unit 14, a first control target switching unit 15, a first power control unit 16, and a first high-frequency power source-dedicated reference clock generation unit 17. The first power control unit 16 includes a first comparison unit 161 and a first compensation unit 162.

In addition, the first high-frequency power source 10 includes a first high-frequency power source-dedicated information storage unit 18 and a first high-frequency power source-dedicated setting value information output unit 19. In addition, the first high-frequency power source-dedicated information storage unit 18 stores first high-frequency power source-dedicated setting value information ST1.

The first high-frequency power source-dedicated setting value information ST1 is information indicating a relationship between the elapsed time from the start point of the cycle within the time of one cycle of the amplitude modulation and a first high-frequency power source-dedicated setting value.

The first high-frequency power source-dedicated setting value information output unit 19 outputs the first high-frequency power source-dedicated setting value corresponding to the elapsed time or a command signal corresponding to the first high-frequency power source-dedicated setting value based on the first high-frequency power source-dedicated setting value information ST1.

In the first high-frequency power source 10, a unit that performs calculation processing or signal processing can include, for example, a circuit such as a central processing unit (CPU) and a field programmable gate array (FPGA), a storage medium such as a memory, or the like. In addition, operation of each unit can be controlled in accordance with a control program stored in advance in a read only memory (ROM) or the like, and processing of input/output, calculation, time measurement, or the like can be performed. Note that the first high-frequency power source 10 includes the first high-frequency power source-dedicated reference clock generation unit 17, and the processing is executed in each control cycle based on the clock signal output from the first high-frequency power source-dedicated reference clock generation unit 17. A frequency of a reference clock of the first high-frequency power source-dedicated reference clock generation unit 17 in the embodiment is 100 MHz, but is not limited to this frequency.

Note that, also in the first matcher 20, the second high-frequency power source 30, and the second matcher 40 to be described below, a unit that performs calculation processing or signal processing can include, for example, a circuit such as a CPU and an FPGA, a storage medium such as a memory, or the like. In addition, a reference clock generation unit is provided. Since these are similar to the above description, the similar description will be omitted when the first matcher 20, the second high-frequency power source 30, and the second matcher 40 are described.

The first high-frequency power source-dedicated communication unit 11 can communicate with other devices.

For example, the first high-frequency power source-dedicated communication unit 11 can output, to the other devices, a signal generated in the first high-frequency power source 10. In addition, for example, the first high-frequency power source-dedicated communication unit 11 can receive the command IS and the various setting values St output from the external control device 101 and output the command IS and the various setting values St toward each unit in the first high-frequency power source 10. In addition, the first high-frequency power source-dedicated communication unit 11 can receive the cycle start signal PS output from the cycle start signal generation device 102 and output the cycle start signal PS toward each unit in the first high-frequency power source 10.

Besides, the first high-frequency power source-dedicated communication unit 11 can communicate with the external control device 101, the cycle start signal generation device 102, the first matcher 20, the second matcher 40, or the like, but the description thereof will be omitted. Note that the communication in the embodiment can be performed using various types of communication means such as serial communication. In addition, the communication also includes an output and an input of a voltage signal (a high level (for example, a voltage signal of 5 V) or a low level (for example, a voltage signal of 0 V)).

The first high-frequency voltage output unit 12 outputs the forward wave voltage VF1. At this time, since an output level thereof is controlled based on an amplitude control signal Vcnt from the first compensation unit 162, the first high-frequency voltage output unit 12 can output high-frequency power having a desired power value.

In addition, as described above, the high-frequency power source device such as the first high-frequency power source 10 or the second high-frequency power source 30 can perform frequency matching, frequency modulation control, or the like. Therefore, the first high-frequency power source 10 sets necessary information when performing the frequency matching, the frequency modulation control, or the like. The necessary information is, for example, information related to a frequency such as a fundamental frequency, an offset frequency, and a frequency fluctuation range.

In addition, the necessary information is set as the first high-frequency power source-dedicated setting value information ST1, and the first high-frequency power source-dedicated setting value information ST1 is stored in the first high-frequency power source-dedicated information storage unit 18. The first high-frequency power source-dedicated setting value information output unit 19 can read the first high-frequency power source-dedicated setting value information ST1 from the first high-frequency power source-dedicated information storage unit 18 and output the information toward the first high-frequency voltage output unit 12. The first high-frequency voltage output unit 12 can receive the first high-frequency power source-dedicated setting value information ST1 and use the information for control.

Note that it is not necessary to set, as the first high-frequency power source-dedicated setting value information ST1, all the setting values required for controlling the first high-frequency power source 10. For example, a setting value used for control other than the amplitude modulation control may be input from the external control device 101. In addition, even if the setting value is used for the amplitude modulation control, the setting value is not set as the first high-frequency power source-dedicated setting value information ST1, but may be separately stored when the setting value is a fixed value.

The same applies to the first matcher 20, the second high-frequency power source 30, and the second matcher 40 to be described below, and it is not necessary to set, as the setting value information ST, all setting values required for controlling the devices.

The first high-frequency power source-dedicated sensor 13 is provided at an output end of the first high-frequency power source 10, allows the forward wave voltage VF1 output from the first high-frequency voltage output unit 12 to pass, and outputs the forward wave voltage VF1 toward the first matcher 20. In addition, the forward wave voltage VF1 output from the first high-frequency voltage output unit 12 is detected, and a forward wave voltage detection signal vf1g that is a detection signal of the forward wave voltage VF1 is output toward the first power information calculation unit 14. In addition, the reflected wave voltage VR1 which is reflected from the load 103 side and returns to the first high-frequency power source 10 is detected, and a reflected wave voltage detection signal vr1g which is a detection signal of the reflected wave voltage VR1 is output toward the first power information calculation unit 14. As the first high-frequency power source-dedicated sensor 13, for example, a directional coupler can be used.

Note that an A/D converter (not illustrated) may be provided between the first high-frequency power source-dedicated sensor 13 and the first power information calculation unit 14.

The first power information calculation unit 14 receives the forward wave voltage detection signal vf1g and the reflected wave voltage detection signal vr1g output from the first high-frequency power source-dedicated sensor 13 and calculates and outputs the forward wave power value pf1, the reflected wave power value pr1, the load-side power value pL1, and the reflection coefficient absolute value Γ1 based on the received signals. Although detailed descriptions thereof are omitted because calculation methods thereof are known, for example, the values can be calculated as follows. Note that calculated information can be output as the monitor information IFM to the external control device 101 or the like.

In addition, the forward wave power value pf1 for each output level at the time of the amplitude modulation can be calculated. Therefore, for example, a cycle start time point of the amplitude modulation may be recognized by inputting the cycle start signal PS. This enables the first power information calculation unit 14 to recognize the output level at the time of the amplitude modulation. The same applies to the reflected wave power value pr1, the load-side power value pL1, and the reflection coefficient absolute value Γ1.

### Forward Wave Power Value pf1

The first power information calculation unit 14 calculates the forward wave power value pf1 based on the input forward wave voltage detection signal vf1g. For example, the input forward wave voltage detection signal vf1g is squared, information of an unnecessary frequency component is then cut by a low-pass filter (for example, an IIR filter or the like) that extracts a desired component, and a constant for conversion into the forward wave power value pf1 is further multiplied to calculate the forward wave power value pf1. The forward wave power value pf1 can be calculated by the forward wave voltage detection signal vf1g^2/R (R: a gain corresponding to a resistance value), for example.

### REFLECTED WAVE POWER VALUE PR1

The first power information calculation unit 14 calculates the reflected wave power value pr1 based on the input reflected wave voltage detection signal vr1g. For example, the input reflected wave voltage detection signal vr1g is squared, information of an unnecessary frequency component is then cut by a low-pass filter (for example, an IIR filter or the like) that extracts a desired component, and a constant for conversion into the reflected wave power value pr1 is further multiplied to calculate the reflected wave power value pr1. The reflected wave power value pr1 can be calculated by, for example, the reflected wave voltage detection signal vr1g^2/R (R: a gain corresponding to a resistance value).

### Load-side Power Value pL1

The first power information calculation unit 14 calculates the load-side power value pL1 based on the forward wave power value pf1 and the reflected wave power value pr1 calculated above. For example, the load-side power value pL1 can be calculated by the forward wave power value pf1 - the reflected wave power value pr1 (subtracting the reflected wave power value pr1 from the forward wave power value pf1).

### Reflection Coefficient Absolute Value Γ1

The first power information calculation unit 14 calculates the reflection coefficient absolute value Γ1 based on the forward wave power value pf1 and the reflected wave power value pr1. The reflection coefficient absolute value Γ1 can be calculated by, for example, √(reflected wave power value pr1/forward wave power value pf1).

The first control target switching unit 15 receives the forward wave power value pf1 and the load-side power value pL1 and outputs either the forward wave power value pf1 or the load-side power value pL1 as a control target to the first comparison unit 161. The control target is determined based on, for example, the command signal IS output from the external control device 101 or the first high-frequency power source-dedicated setting value information output unit 19. The forward wave power constant control is performed in a case where the forward wave power value pf1 is the control target, and the load-side power constant control is performed in a case where the load-side power value pL1 is the control target.

The first comparison unit 161 subtracts the power value which is the control target (the forward wave power value pf1 or the load-side power value pL1) from the target power value pt1 and outputs the subtraction result as error information Δpf1 to the first compensation unit 162. The target power value pt1 is output from the first high-frequency power source-dedicated setting value information output unit 19.

The first compensation unit 162 generates an amplitude control signal Vcnt for controlling the amplitude of the forward wave voltage VF1 according to the error information Δpf1 and outputs the amplitude control signal Vcnt toward the first high-frequency voltage output unit 12. This enables the amplitude of the forward wave voltage VF1 to be adjusted, and eventually, enables the forward wave power value pf1 to be adjusted.

For example, when the target power value pt1 is 1,000 (W) and the forward wave power value pf1 is 950 (W), a difference of 50 (W) is insufficient with respect to the target power value pt1. Hence, the first compensation unit 162 determines and outputs a magnitude of the amplitude control signal Vcnt to increase, by 50 (W), the forward wave power value pf1 that is supplied to the load 103. For such control of the amplitude of the forward wave voltage VF1, for example, a known technique such as PI control or PID control can be used.

At this time, since the first high-frequency power source-dedicated setting value information output unit 19 outputs the corresponding target power value pt1 in accordance with a change in the output level at the time of the amplitude modulation, the forward wave power value pf1 can be changed in multiple stages.

### Details of First Matcher 20

The first matcher 20 includes an input end 20a, an output end 20b, a communication terminal 20c, a communication terminal 20d, the first matcher-dedicated communication unit 21, a first matcher-dedicated sensor 22, a first matcher-dedicated matching circuit 23, a first matcher-dedicated calculation unit 24, a first matcher-dedicated control unit (control circuit) 25, and a first matcher-dedicated reference clock generation unit 26.

In addition, the first matcher 20 includes a first matcher-dedicated information storage unit 27 and a first matcher-dedicated setting value information output unit (matcher-dedicated setting value information output circuit) 28. In addition, the first matcher-dedicated information storage unit 27 stores the first matcher-dedicated setting value information ST2.

The first high-frequency power source 10 can be connected to the input end 20a. The input end 20a can receive power from the first high-frequency power source 10 in a state in which the first high-frequency power source 10 is connected to the input end 20a.

The load 103 can be connected to the output end 20b via the superimposition output unit 50. In a state in which the load 103 is connected to the output end 20b via the superimposition output unit 50, the output end 20b can supply power to the load 103 via the superimposition output unit 50.

The first high-frequency power source 10 can be connected to the communication terminal 20c. In a state in which the first high-frequency power source 10 is connected to the communication terminal 20c, the first matcher-dedicated communication unit 21 can communicate with the first high-frequency power source 10 via the communication terminal 20c.

One other device can be connected to the communication terminal 20d. In a state in which the other device is connected to the communication terminal 20d, the first matcher-dedicated communication unit 21 can communicate with the other device via the communication terminal 20d. For example, the cycle start signal PS output from the cycle start signal generation device 102 is input and output toward the first matcher-dedicated setting value information output unit 28, the first matcher-dedicated calculation unit 24, and the first matcher-dedicated control unit 25.

Note that the communication in the embodiment can be performed using various types of communication means such as serial communication. In addition, the communication also includes an output and an input of a voltage signal (the high level (for example, the voltage signal of 5 V) or the low level (for example, the voltage signal of 0 V)).

In addition, the first matcher-dedicated communication unit 21 can communicate with the external control device 101, the cycle start signal generation device 102, the first high-frequency power source 10, the second high-frequency power source 30, the second matcher 40, and the like, but the description thereof will be omitted.

The first matcher-dedicated sensor 22 is provided in the vicinity of the input end 20a of the first matcher 20 and detects information for calculating a load-side impedance Z1 when the load 103 side is viewed from the input end 20a of the first matcher 20 (equivalent to the output end of the first high-frequency power source 10) or information for calculating the reflection coefficient ρ1 at the input end 20a of the first matcher 20. Since the load-side impedance Z1 and the reflection coefficient ρ1 can be converted into each other, either one may be detected.

In a case where the load-side impedance Z1 is calculated, for example, a voltage detector and a current detector are used as the first matcher-dedicated sensor 22. In this case, a voltage at the input end of the first matcher 20 is detected by the voltage detector, and a voltage detection signal v1 is output as a detection signal of the voltage. In addition, a current at the input end 20a of the first matcher 20 is detected by the current detector, and a current detection signal i1 is output as a detection signal of the current. The voltage detection signal v1 and the current detection signal i1 are output toward the first matcher-dedicated calculation unit 24.

In a case where the reflection coefficient ρ1 at the input end 20a of the first matcher 20 is calculated, for example, a directional coupler is used as the first matcher-dedicated sensor 22. In this case, the forward wave voltage VF1 output from the first high-frequency power source 10 is detected, a forward wave voltage detection signal vf1m is output as a detection signal of the forward wave voltage VF1, the reflected wave voltage VR1 which is reflected from the load 103 side and returns to the first high-frequency power source is detected, and a reflected wave voltage detection signal vr1m is output as a detection signal of the reflected wave voltage VR1. The forward wave voltage detection signal vf1m and the reflected wave voltage detection signal vr1m are output toward the first matcher-dedicated calculation unit 24.

Note that an A/D converter (not illustrated) may be provided between the first matcher-dedicated sensor 22 and the first matcher-dedicated calculation unit 24.

The first matcher-dedicated matching circuit 23 is provided between the first matcher-dedicated sensor 22 and the superimposition output unit 50. The first matcher-dedicated matching circuit 23 internally includes a variable element such as a variable capacitor that can change capacitance, for example, and can change a variable value (the capacitance in the case of the variable capacitor and inductance in the case of a variable inductor) of the variable element in accordance with a command from the first matcher-dedicated control unit 25 to be described below and adjust the load-side impedance Z1 when the load 103 side is viewed from the input end of the first matcher 20. The variable inductor may be provided as the variable element. In addition, a drive circuit (not illustrated) is provided to change the capacitance of the variable element in accordance with the command from the first matcher-dedicated control unit 25.

In addition to the variable element, an inductor having a fixed value of inductance may be often provided. In addition, a capacitor having a fixed value of capacitance may be provided.

As the first matcher-dedicated matching circuit 23, a so-called matching circuit of an inverted L type (also referred to as an L type), a π type, or the like is often used.

Note that there are various types of variable capacitors. For example, there is a variable capacitor of a type in which capacitance is changed by changing a distance between electrodes. In addition, there is a variable capacitor of a type in which a plurality of capacitors connected to a switch in series are connected in parallel, and total capacitance is changed by changing a state (ON/OFF) of the switch. In this manner, a type of variable capacitor is not limited.

The first matcher-dedicated calculation unit 24 calculates the reflection coefficient ρ1 or the load-side impedance Z1 based on the information output from the first matcher-dedicated sensor 22 and outputs the reflection coefficient ρ1 or the load-side impedance Z1 as the load information IFL on the first matcher 20 side toward the first matcher-dedicated control unit 25. The reflection coefficient ρ1 and the load-side impedance Z1 are the load information IFL indicating a state of the load. Note that the first matcher-dedicated calculation unit 24 may include, on an input side, a filter that removes an unnecessary signal component (for example, a harmonic component). At this time, a filter method may be selected, as appropriate.

In addition, the calculated load information IFL may be output to the outside via the first matcher-dedicated communication unit 21. Note that, although FIG. 1 illustrates the example in which the load information IFL is transmitted to the external control device 101 via the first matcher-dedicated communication unit 21 and the first high-frequency power source-dedicated communication unit 11, the load information IFL may be transmitted from the first matcher-dedicated communication unit 21 to the external control device 101 without being transmitted via the first high-frequency power source-dedicated communication unit 11.

The reflection coefficient ρ1 can be calculated by, for example, the reflected wave voltage detection signal vr1m/the forward wave voltage detection signal vf1m. In addition, the load-side impedance Z1 can be calculated by, for example, the voltage detection signal v1/the current detection signal i1. In addition, the load-side impedance Z1 can be calculated based on, for example, a magnitude of the voltage detection signal v1, a magnitude of the current detection signal i1, and a phase difference θ between the voltage detection signal v1 and the current detection signal i1. Since calculation methods of the reflection coefficient ρ1 and the load-side impedance Z1 are well known, the description thereof will be omitted.

In addition, since the reflection coefficient ρ1 and the load-side impedance Z1 can be converted into each other, in order to simplify the description, regarding the first matcher-dedicated calculation unit 24, only one of the reflection coefficient ρ1 and the load-side impedance Z1 may be described in the following description.

The first matcher-dedicated control unit 25 outputs a command signal for controlling the variable value of the variable element inside the first matcher-dedicated matching circuit 23 such that the absolute value Γ1 of the reflection coefficient ρ1 approaches a target reflection coefficient absolute value Γ0 (usually 0), by using the load information IFL on the first matcher 20 side output from the first matcher-dedicated calculation unit 24. In other words, the command signal for controlling the variable value of the variable element inside the first matcher-dedicated matching circuit 23 is output such that the load-side impedance Z1 becomes a complex conjugate of the output impedance Z0 of the first high-frequency power source 10. For example, in a case where the variable element included in the first matcher-dedicated matching circuit 23 is the variable capacitor, the command signal for controlling the capacitance is output. More specifically, for example, capacitance of the variable capacitor, with which the absolute value Γ1 of the reflection coefficient ρ1 is predicted to be closest to the target reflection coefficient absolute value Γ0, is calculated, and a command signal is output to a drive circuit that drives the variable capacitor to reach the capacitance.

When the first matcher-dedicated control unit 25 performs the control as described above, the first matcher-dedicated control unit 25 can use the setting value information ST2 for the first matcher 20 output from the first matcher-dedicated setting value information output unit 28 or a command signal corresponding to the setting value information ST2. In addition, synchronization with another device can be performed by the cycle start signal PS.

### Regarding Setting Value Information ST

The setting value information ST can be variously set. The setting value information ST and related matters will be described below using some setting examples.

### Setting Example of Setting Value Information ST

(Part 1)

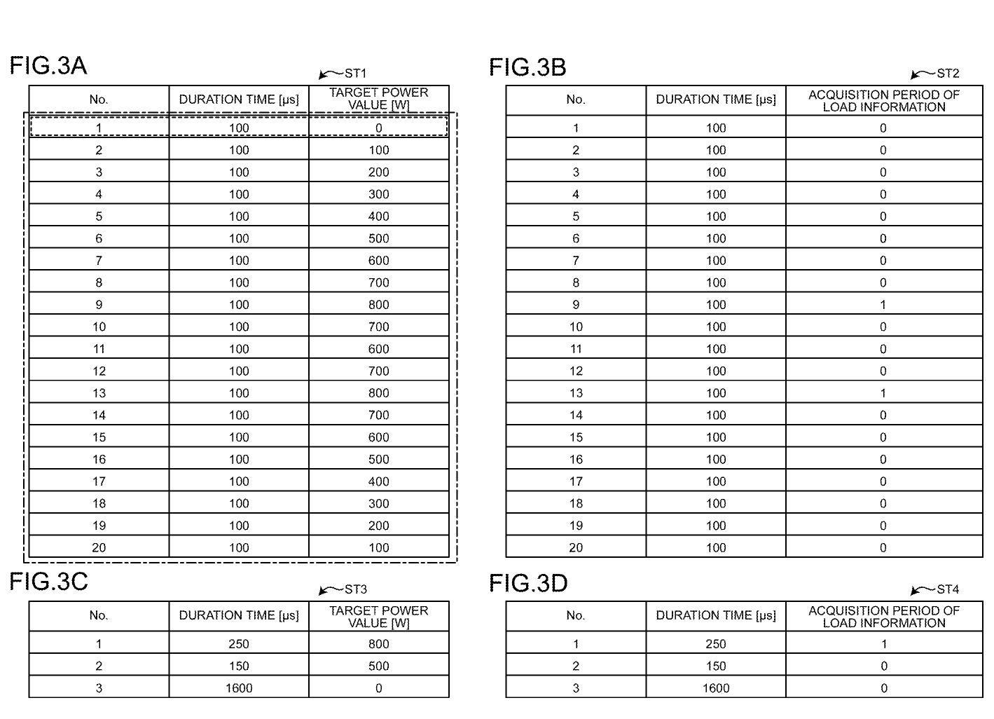

FIGS. 3A to 3D are tables for describing a setting example of the setting value information.

FIG. 3A illustrates an example of the first high-frequency power source-dedicated setting value information ST1 corresponding to FIG. 2A. In the first high-frequency power source-dedicated setting value information ST1, "No." indicating an order, a duration time (μs), and a target power value (W) of the first high-frequency power source are provided as setting items.

FIG. 3B illustrates an example of the first matcher-dedicated setting value information ST2 corresponding to FIG. 2B. In the first matcher-dedicated setting value information ST2, a relationship between a relationship between "No." indicating an order, the duration time (μs), and an acquisition period of the load information IFL is illustrated.

FIG. 3C illustrates an example of the second high-frequency power source-dedicated setting value information ST3 corresponding to FIG. 2C. In the second high-frequency power source-dedicated setting value information ST3, "No." indicating an order, the duration time (μs), and the target power value (W) of the second high-frequency power source are provided as setting items.

FIG. 3D illustrates an example of the second matcher-dedicated setting value information ST4 corresponding to FIG. 2D. The second matcher-dedicated setting value information ST4 indicates a relationship between "No." indicating an order, the duration time (μs), and the acquisition period of the load information IFL.

Here, when the acquisition period of the load information IFL is "1", this indicates a period during which the load information IFL is acquired, and when the acquisition period is "0", this indicates a period during which the load information IFL is not acquired.

Note that, in FIGS. 3A to 3D, the order of the columns is random. In addition, since items of information constituting the setting value information ST are sequentially read by the corresponding setting value information output unit 19 or 28, information of "No." is not essential. The same concept is applied to the following description.

In this manner, the setting value information ST can be described in a table format. Also, the setting value information ST is configured to include a plurality of sets of information as surrounded by a one-dot chain line in FIG. 3A, for example, and one set of information surrounded by a broken line in FIG. 3A includes information of the elapsed time and information of at least one type of setting item (for example, the target power value).

The setting values stored as the setting value information ST are sequentially read by the corresponding setting value information output unit (for example, the first high-frequency power source-dedicated setting value information output unit 19 or the first matcher-dedicated setting value information output unit 28), and the corresponding processing is performed.

In the example of FIG. 3A, since the target power value is stored as the first high-frequency power source-dedicated setting value information ST1, the first high-frequency power source-dedicated setting value information output unit 19 outputs a setting value of the target power value corresponding to the elapsed time toward the first comparison unit 161. For example, information of 100 W that is the setting value of the target power value of the first high-frequency power source 10 in the period of No. 2 is output as the target power value pt1 toward the first comparison unit 161. This enables the first high-frequency power source 10 to control the power value to be output.

Therefore, use of information of the setting value information ST1 enables the first high-frequency power source 10 to perform the amplitude modulation illustrated in FIG. 2A. In addition, use of information of the setting value information ST2 enables the first matcher 20 to acquire the load information IFL at an appropriate timing.

In this manner, even in the case of performing complicated amplitude modulation as illustrated in FIGS. 2A to 2E, it is easy to set a setting value (a target power value or the like) since it is only necessary to set the setting value (the target power value or the like) corresponding to an elapsed time from a start point of a cycle within a time of one cycle of amplitude modulation, as illustrated in FIGS. 3A to 3D.

Note that, as illustrated in FIGS. 2A to 2E, the same waveform is often repeated in the amplitude modulation. In this case, the setting value information ST illustrated in FIGS. 3A to 3D may be repeatedly used. Namely, it is only necessary to set the setting value information ST for one cycle of the amplitude modulation.

### Setting Example of Setting Value Information ST (Part 2)

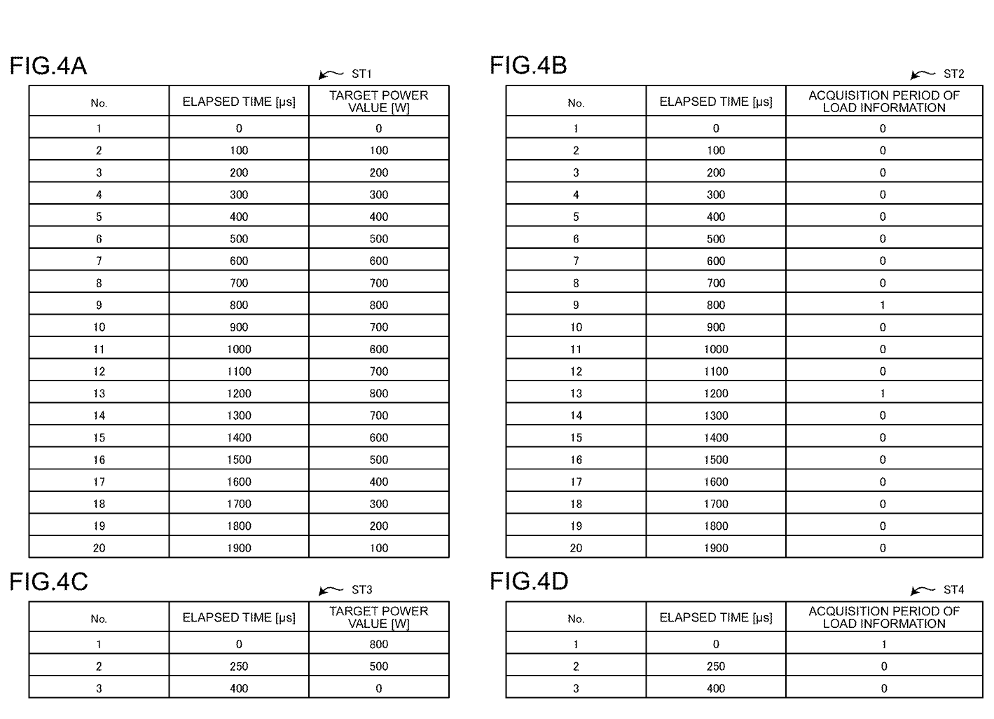

FIGS. 4A to 4D are tables for describing another setting example of the setting value information.

FIG. 4A illustrates another example of the first high-frequency power source-dedicated setting value information ST1 corresponding to FIG. 2A.

In addition, FIG. 4B illustrates another example of the first matcher-dedicated setting value information ST2 corresponding to FIG. 2B.

In addition, FIG. 4C illustrates another example of the second high-frequency power source-dedicated setting value information ST3 corresponding to FIG. 2C.

In addition, FIG. 4D illustrates another example of the second matcher-dedicated setting value information ST4 corresponding to FIG. 2D.

FIGS. 4A to 4D are obtained by converting the duration time (μs) of the setting value information illustrated in FIGS. 3A to 3D into the elapsed time (μs).

Namely, in FIGS. 3A to 3D, the duration time is used as a time element and may be described as the elapsed time as in FIGS. 4A to 4D. For example, in FIG. 3A, since the duration time of No. 1 is 100 μs, and the duration time of No. 2 is 100 μs, the elapsed time at an execution start time of No. 3 becomes 200 μs. Therefore, the elapsed time at the execution start time of No. 3 in FIG. 4A is 200 μs. In addition, as described above, in the example of FIGS. 2A to 2E, since the time of one cycle of the amplitude modulation is 2,000 μs, the elapsed time at an execution start time of No. 20 in FIG. 4A is 1,900 μs, and the duration time of No. 20 is 100 μs.

As can be known from the above description, the time may be described by a duration time or may be described by an elapsed time, but in any case, the setting value information ST illustrated in FIGS. 3A to 4D indicates a relationship between an elapsed time from a start point of a cycle within a time of one cycle of the amplitude modulation and a setting value.

Hereinafter, operation of individual devices will be described in a case where a time when the cycle start signal PS is input is set as the start point of the cycle within the time of one cycle of the amplitude modulation (the elapsed time is 0).

The examples illustrated in FIGS. 3A to 4D describe that the first matcher 20 acquires the load information IFL in a period of No. 9 and a period of No. 13. Therefore, in the period of No. 9 and the period of No. 13, the first matcher-dedicated setting value information output unit 28 outputs, to the first matcher-dedicated control unit 25, a command signal to employ the load information IFL output from the first matcher-dedicated calculation unit 24. The first matcher-dedicated control unit 25 performs matching operation such that the absolute value Γ1 of the reflection coefficient ρ1 approaches the target reflection coefficient absolute value Γ0 (normally 0) by using the adopted load information IFL.

At this time, the matching operation is performed using the load information IFL acquired in the period of No. 9 and the period of No. 13 also in a period other than the period of No. 9 and the period of No. 13. In addition, the examples illustrated in FIGS. 3A to 4D describe that the second matcher 40 acquires the load information IFL in a period of No. 1. Therefore, the second matcher 40 acquires the load information IFL in the period of No. 1 and performs the matching operation by using the acquired load information IFL. Since this control is similar to that of the first matcher 20, the description thereof will be omitted.

As described above, the control corresponding to FIGS. 2A to 2E can be performed.

Here, the setting value information ST illustrated in FIGS. 3A to 4D can be simplified. For example, in FIGS. 3B and 4B, since the setting values of the acquisition periods of the load information in the periods No. 1 to No. 8 are 0, the setting values can be combined into 1. Specifically, in FIG. 3B,

the duration time of the period of No. 1 is set to 800 μs, the acquisition period of the loading information is set to 0,

the duration time of the period of No. 2 is set to 100 μs, and the acquisition period of the loading information is set to 1,

the duration time of the period of No. 3 is set to 300 μs and the acquisition period of the loading information is set to 0,

the duration time of the period of No. 4 is set to 100 μs, and the acquisition period of the loading information is

set to 1, and

the duration time of the period of No. 5 can be set to 700 μs, and the acquisition period of the loading information can be set to 0.

Also in FIG. 4B, items having the same setting value can be combined with a similar concept.

However, the setting value information ST illustrated in FIGS. 3A to 4D is not simplified intentionally in order to clarify the correspondence with FIGS. 2A to 2E.

Namely, in the first matcher-dedicated setting value information ST2 illustrated in FIGS. 3B and 4B, the setting value information is set at the same time intervals as in the first high-frequency power source-dedicated setting value information ST1 illustrated in FIGS. 3A and 4A. Similarly, in the second matcher-dedicated setting value information ST4 illustrated in FIGS. 3D and 4D, the setting value information is set at the same time interval as in the second high-frequency power source-dedicated setting value information ST3 illustrated in FIGS. 3C and 4C.

This is because, in the examples of FIGS. 3A to 4D, the acquisition periods of the load information IFL in the impedance matcher (the first matcher 20 or the second matcher 40) are associated with the target power values of the corresponding high-frequency power source device (the first high-frequency power source 10 or the second high-frequency power source 30), respectively.

In such a case, as illustrated in FIGS. 3A to 4D, time intervals of the setting value information for the impedance matcher (the first matcher-dedicated setting value information ST2 or the second matcher-dedicated setting value information ST4) may be set at the same time intervals as the setting value information (the first high-frequency power source-dedicated setting value information ST1 or the second high-frequency power source-dedicated setting value information ST3) of the corresponding high-frequency power source device (the first high-frequency power source 10 or the second high-frequency power source 30). In this manner, the acquisition period of the load information IFL in the impedance matcher (the first matcher 20 or the second matcher 40) can be easily set.

### SETTING EXAMPLE OF SETTING VALUE INFORMATION (PART 3)

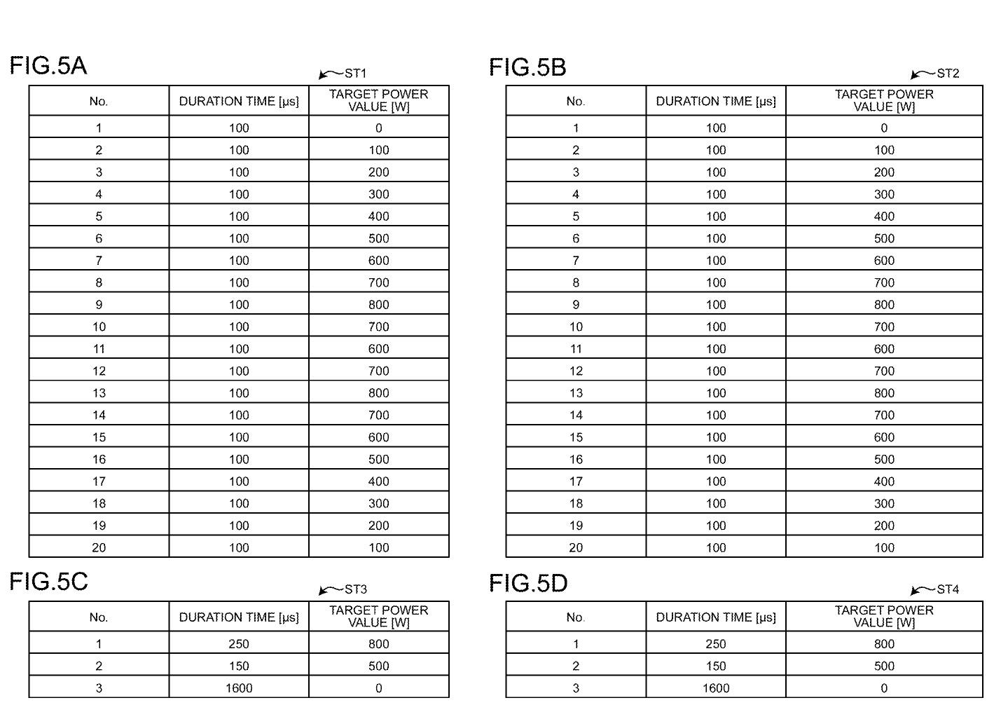

FIGS. 5A to 5D are tables for describing still another setting example of the setting value information.

FIG. 5A illustrates an example of the first high-frequency power source-dedicated setting value information ST1 corresponding to FIG. 2A. FIG. 5B is the same as FIG. 3A.

FIG. 5B illustrates an example of the first matcher-dedicated setting value information ST2 corresponding to FIG. 2B. FIG. 5B is the same as FIG. 5A.

FIG. 5C illustrates an example of the second high-frequency power source-dedicated setting value information ST3 corresponding to FIG. 2C. FIG. 5C is the same as FIG. 5C.

FIG. 5D illustrates an example of the second matcher-dedicated setting value information ST4 corresponding to FIG. 2D. FIG. 5D is the same as FIG. 5C.

As described above, in a case where the acquisition period of the load information IFL is related to the target power value, the first high-frequency power source-dedicated setting value information ST1 can be used as the first matcher-dedicated setting value information ST2. Similarly, the second high-frequency power source-dedicated setting value information ST3 can be used as the second matcher-dedicated setting value information ST4.

In such a case, in first matching and second matching, a relationship between the target power value and the acquisition period of the load information IFL may be additionally stored. For example, the first matcher 20 may recognize, as the acquisition period of the load information, a period during which the target power value of the first high-frequency power source 10 is 800 W. In addition, automatic determination may be performed such that the period during which the highest target power value is set in the setting value information is defined as the acquisition period of the load information.

As a matter of course, the period during which the highest target power value is set may not be defined as the acquisition period of the load information, but a predetermined range (for example, a period during which the target power value is 600 W or higher) may be defined as the acquisition period of the load information.

Since the control in the individual devices is similar to the cases of FIGS. 3A to 4D, the description thereof will be omitted. Note that, in FIGS. 5A to 5D, a time is represented by a duration time and may be represented by an elapsed time.

As illustrated in FIGS. 5A to 5D, it is only necessary to copy the setting value information ST (the first high-frequency power source-dedicated setting value information ST1 or the second high-frequency power source-dedicated setting value information ST3) of the corresponding high-frequency power source device (the first high-frequency power source 10 or the second high-frequency power source 30). In addition, it is also possible to perform control based on the information of the target power value of the high-frequency power source device (the first high-frequency power source 10 or the second high-frequency power source 30).

### Setting Example of Setting Value Information (Part 4)

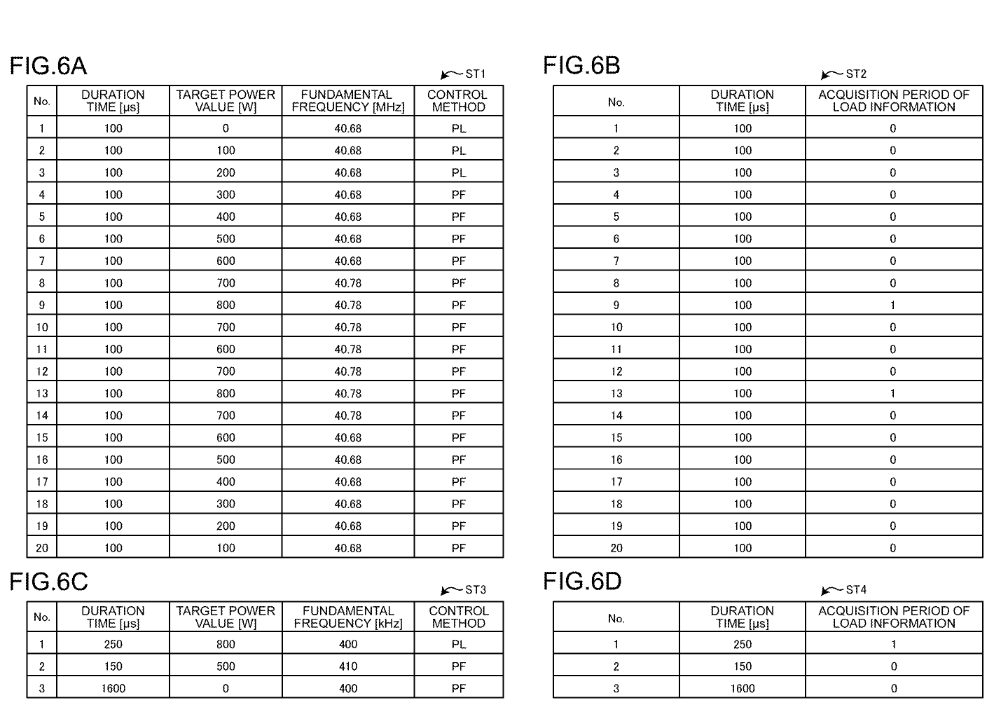

FIGS. 6A to 6D are tables for describing still another setting example of the setting value information.

FIG. 6A is obtained by adding a fundamental frequency and a control method as setting items to the first high-frequency power source-dedicated setting value information ST1 illustrated in FIG. 3A.

FIG. 6B is the same as the first matcher-dedicated setting value information ST2 illustrated in FIG. 3B. Therefore, the description thereof will be omitted.

FIG. 6C is obtained by adding a fundamental frequency and a control method as setting items to the second high-frequency power source-dedicated setting value information ST3 illustrated in FIG. 3C.

FIG. 6D is the same as the second matcher-dedicated setting value information ST4 illustrated in FIG. 3D. Therefore, the description thereof will be omitted.

As illustrated in FIGS. 6A and 6C, the setting item other than "No." and the duration time (μs) of the setting value information ST are not limited to one type, and a plurality of types can be set. In the case of 6A to 6D, in both of FIGS. 6A and 6C, three items of the target power value, the fundamental frequency, and the control method are set as the setting items other than "No." and the duration time (μs). Note that "PL" in the control method denotes load-side power constant control, and "PF" denotes forward wave power constant control.

In the example of FIG. 6A, since the target power value in the period of No. 1 is 0 W, the high-frequency power is not output from the first high-frequency power source 10.

Thereafter, in the period of No. 2, the high-frequency power is output from the first high-frequency power source 10 in the conditions that the target power value is 100 W, the fundamental frequency is 40.68 MHz, and the control method is the load-side power constant control. This load-side power constant control continues to the period of No. 3. In the period of No. 4, the control method is the forward wave power constant control, and thereafter, the forward wave power constant control continues to the period of No. 20.

Thereafter, in the period of No. 8, the fundamental frequency is changed from 40.68 MHz to 40.78 MHz. Thereafter, the fundamental frequency is 40.78 MHz until the period of No. 14, and the fundamental frequency returns to 40.68 MHz in the period of No. 15. Thereafter, the fundamental frequency is 40.68 MHz until the period of No. 20.

Note that, after the period of No. 20 ends, the process returns to No. 1, and the first high-frequency power source-dedicated setting value information is repeatedly used. As a matter of course, this does not apply to a case where the amplitude modulation control is ended, a case where the setting value information is changed, or the like.

Note that the information of the target power value in the first high-frequency power source-dedicated setting value information ST1 illustrated in FIG. 6A is read as the target power value pt1 in FIG. 1 from the first high-frequency power source-dedicated information storage unit 18.

The information of the fundamental frequency in the first high-frequency power source-dedicated setting value information ST1 illustrated in FIG. 6A is read as information such as frequency information FR in FIG. 1 from the first high-frequency power source-dedicated information storage unit 18. The information such as the frequency information FR is output toward the first high-frequency voltage output unit 12, for example.

The information of the control method in the first high-frequency power source-dedicated setting value information ST1 illustrated in FIG. 6A is read as the information of the control method in FIG. 1 from the first high-frequency power source-dedicated information storage unit 18. This information of the control method information is output toward the first control target switching unit 15, for example.

In the example of FIG. 6C, in the period of No. 1, the high-frequency power is output from the second high-frequency power source 30 under the conditions that the target power value is 800 W, the fundamental frequency is 400 kHz, and the control method is the load-side power constant control.

Thereafter, in the period of No. 2, the target power value is 500 W, the fundamental frequency is 410 kHz, and the control method is changed to the forward wave power constant control.

Thereafter, in the period of No. 3, the target power value is 0 W, the fundamental frequency is 400 kHz, and the control method is changed to the forward wave power constant control; however, since the target power value is 0 W, the high-frequency power is not output from the second high-frequency power source 30.

Note that, after the period of No. 3 ends, the process returns to No. 1, and the second high-frequency power source-dedicated setting value information ST3 is repeatedly used. As a matter of course, this does not apply to a case where the amplitude modulation control is ended, a case where the setting value information ST is changed, and the like.

Note that each item of information in the second high-frequency power source-dedicated setting value information ST3 illustrated in FIG. 6C is read from a second high-frequency power source-dedicated information storage unit 29. This is similar to the case of the first high-frequency power source 10 illustrated in FIG. 6A, and thus the description thereof will be omitted.

In this manner, setting of the setting items and the setting values according to the individual devices enables various controls to be performed.

As a matter of course, setting items can be set in addition to the items described above. For example, various setting items such as a command value for performing frequency matching or a command value for performing frequency modulation control for IMD reduction can be set.

### Setting Example of Setting Value Information (Part 5)

FIGS. 7A to 7E are diagrams for describing another example of the amplitude modulation waveform, the acquisition period of the load information IFL, and the cycle start signal PS. Similarly to the example of FIGS. 2A to 2E, a case where a time of one cycle of the amplitude modulation is 2,000 μs, and the amplitude modulation of the same waveform is repeated is illustrated.

As illustrated in FIGS. 7A and 7B, FIGS. 7A to 7E illustrate an example in which a start time point of one cycle of the amplitude modulation of the first high-frequency power source 10 and a start time point of one cycle of the amplitude modulation of the first matcher 20 are set to be later than a time point at which the cycle start signal PS is input, with respect to FIGS. 2A to 2E.

In addition, FIGS. 7A to 7E illustrate the example in which a power ramp time is set when the target power value of the high-frequency power in the second high-frequency power source 30 is changed as illustrated in FIG. 7C. The power ramp time in the target power values is a time when the target power value is slowly changed in a ramp function manner.

In addition, in FIGS. 7A to 7E, as illustrated in FIG. 7D, the acquisition period of the load information IFL in the second matcher 40 is set in accordance with setting of the power ramp time of the second high-frequency power source 30.

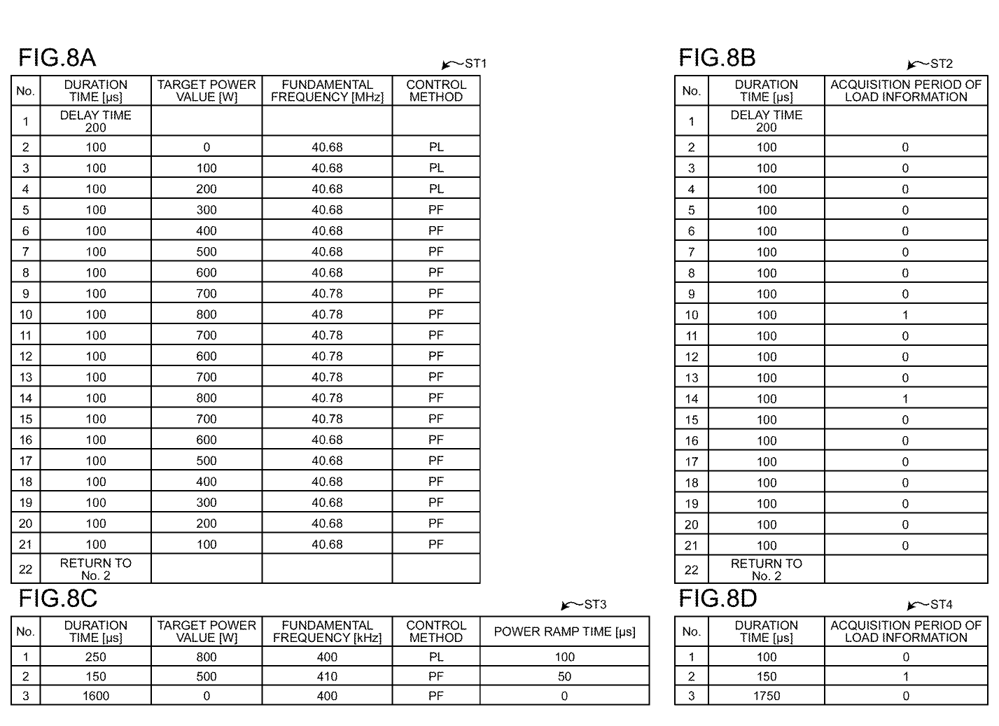

FIGS. 8A to 8D are tables for describing another setting example of the setting value information. FIGS. 8A to 8D illustrate an example of the setting value information ST of each device corresponding to FIGS. 7A to 7E.

FIG. 8A illustrates an example of the first high-frequency power source-dedicated setting value information ST1.

In FIG. 8A, a delay time (200 μS) is set to the duration time of the period of No. 1 of the first high-frequency power source-dedicated setting value information ST1 illustrated in FIG. 6A.

A positive time of the delay time indicates that a start time of the amplitude modulation in the first high-frequency power source 10 is later than a time point at which the cycle start signal PS is input. A negative time of the delay time indicates that the opposite applies thereto.

Therefore, a start time point of one cycle of the amplitude modulation of the first high-frequency power source 10 is delayed by 200 μS from the time point at which the cycle start signal PS is input. Also, the amplitude modulation of the first high-frequency power source 10 is executed based on the items of information of the periods of No. 2 to No. 21. After No. 21, the process returns to No. 2, and thus, from the second cycle of the amplitude modulation, the amplitude modulation is executed based on the items of information of the periods of No. 2 to No. 21 without a delay time.

FIG. 8B is an example of the first matcher-dedicated setting value information ST2. In FIG. 8B, the delay time is set in accordance with the first high-frequency power source-dedicated setting value information ST1 in FIG. 8A.

Therefore, the processing in the first matcher 20 is started from a time point delayed by 200 μS from the time point at which the cycle start signal PS is input and is executed based on the items of information of the periods of No. 2 to No. 21. After No. 21, the process returns to No. 2, and thus, from the second cycle of the amplitude modulation, the amplitude modulation is executed based on the items of information of the periods of No. 2 to No. 21 without a delay time.

FIG. 8C illustrates an example of the second high-frequency power source-dedicated setting value information ST3. FIG. 8C is obtained by adding a power ramp time as a setting item to the second high-frequency power source-dedicated setting value information ST3 illustrated in FIG. 6A.

As illustrated in FIG. 8C, since the power ramp time is set in the period of No. 1 and the period of No. 2 of the second high-frequency power source 30, the amplitude modulation waveform of the second high-frequency power source 30 is obtained as illustrated in FIG. 7C.

FIG. 8D is an example of the second matcher-dedicated setting value information ST4. In FIG. 8D, the acquisition period of the load information IFL is set to correspond to the power ramp time set in the second high-frequency power source-dedicated setting value information ST3 of FIG. 8C.

Namely, the duration time of the period of No. 1 of the second high-frequency power source 30 is 250 μs, and the target power value of 800 W is obtained in a period of 150 μs after a time of 100 μs elapses from the start of the period of No. 1 since the power ramp time is set to 100 μs. Therefore, in the second matcher-dedicated setting value information ST4, the duration time of the period of No. 1 is 100 μs, and the load information IFL is not acquired in this period. In addition, the duration time of the period of No. 2 is 150 μs, and the load information IFL is acquired in this period.

Since the load information IFL is not acquired in the subsequent period, the duration time of the period of No. 3 is 1,750 μs, and the load information IFL is not acquired in this period.

As can be known from FIGS. 7 to 8D, in the first high-frequency power source 10 and the first matcher 20 in which the delay time is set, the start point of the cycle within the time of one cycle of the amplitude modulation is delayed by the delay time. Therefore, the first high-frequency power source 10 and the first matcher 20 do not use the time point at which the cycle start signal PS is input as the start point of the cycle within the time of one period of the amplitude modulation, but use, as the start point, a time point shifted by the delay time.

In other words, it is assumed that the time point at which the cycle start signal PS generated for each time of one period of the amplitude modulation is input or the time point obtained by adding the delay time to the time point at which the cycle start signal PS is input is the start point of the cycle within the time of one cycle of the amplitude modulation.

Although the example in which the delay time is set for the first high-frequency power source 10 and the first matcher 20 has been described above, the delay time may be set for the second high-frequency power source 30 and the second matcher 40.

In addition, although the example in which the power ramp time is set for the second high-frequency power source 30 has been described above, the power ramp time may be set for the first high-frequency power source 10. As a matter of course, the first matcher 20 may set the first matcher-dedicated setting value information ST2 in consideration of the power ramp time set for the first high-frequency power source 10.

### Setting Example of Setting Value Information (Part 6)

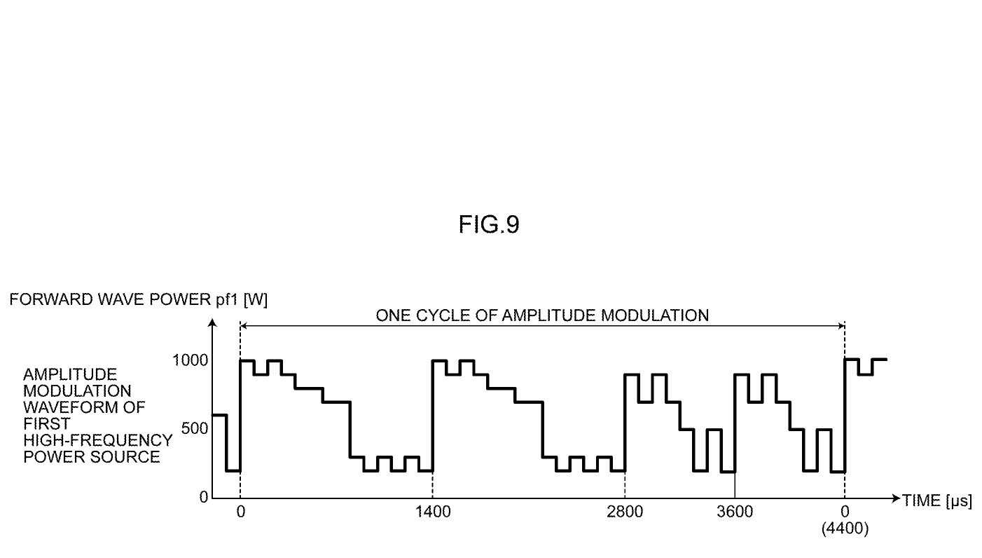

FIG. 9 is a graph illustrating another example of the amplitude modulation waveform of the first high-frequency power source 10.

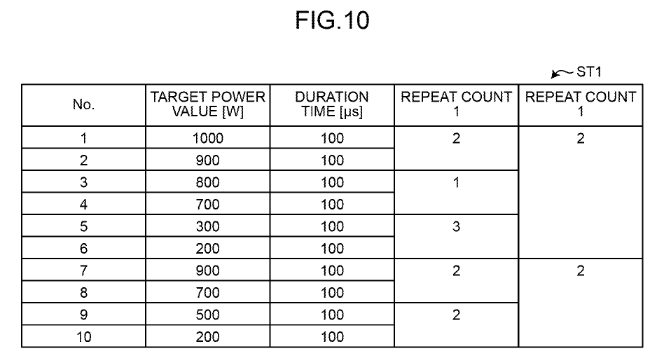

FIG. 10 is a table illustrating an example of the first high-frequency power source-dedicated setting value information ST1 corresponding to FIG. 9.

FIG. 10 illustrates that a repeat count can be set for one continuous set of information in the setting value information ST1.

In FIG. 9, the target power value changes from 1000 W to 900 W, to 1000 W, and to 900 W in an initial period in one cycle of the amplitude modulation. Namely, a part in which the value changes from 1000 W to 900 W is repeated twice. Therefore, as illustrated in FIG. 10, a repeat count for this period may be twice. This facilitates setting of the target power value.

On the other hand, since is no repetition is performed in the subsequent period during which the target power value changes from 800 W to 700 W, the repeat count is once. Note that, in a case where the repeat count is once, the repeat count can be omitted.

In addition, in FIG. 9, a waveform in the period during which the elapsed time from the start point of the cycle within the time of one cycle of the amplitude modulation is 0 to 1,400 μs is repeated even in the period of 1,400 to 2,800 μs. Therefore, the repeat count for the information in the period during which the elapsed time is 0 to 1,400 μs may be twice.

Similarly, the repeat count may be twice for the information of a period during which the elapsed time is 2,800 to 3,600 μs.

In this manner, a plurality of sets of information to be repeated are arbitrary. For example, the repeat count may be set for two sets of information, or the repeat count may be set for three sets of information.

In addition, the repeat count may be set for information including information for which the repeat count is set and other information.

Further, although not illustrated in FIGS. 9 and 10, the repeat count for the entire information may be set.

As can be known from the examples described above, when the repeat count can be set for the information for which the repeat count is set and the other information, the setting value information for a long period of time can be easily created. A plasma treatment process includes many repetitive patterns, thus being very useful.

As a matter of course, the above concept is similar in other items of setting value information (the first matcher-dedicated setting value information ST2, the second high-frequency power source-dedicated setting value information ST3, and the second matcher-dedicated setting value information ST4).

As described above, in the embodiment, since the setting value information ST for each device is used when the amplitude modulation is performed, the amplitude modulation can be easily set.

### Effects of Case Where Setting Value Information ST for High-Frequency Power Source Device Is Not Used

As described above, in recent years, with the advancement of the plasma treatment process, the amplitude modulation waveform has become complicated, for example, the amplitude modulation is performed with a level change of three or more stages, and thus the amount of information transmitted from the external control device 101 to the high-frequency power source device tends to increase. As a result, a time taken to transmit the high-frequency power source-dedicated setting value information from the external control device 101 to the high-frequency power source device is prolonged (for example, by about 1 ms). In this case, it is not possible to respond to a request for changing the setting value such as the target power value in a short time (for example, within hundreds of microseconds).

For example, in a case where the amplitude modulation is performed by the high-frequency power source device (for example, the first high-frequency power source 10 or the second high-frequency power source 30), it is necessary to set the following setting values (i) to (iii) for each predetermined period. In addition, these setting values are transmitted from the external control device 101 to the high-frequency power source device in accordance with progress of the plasma treatment process.

However, the transmission cannot be performed in advance with a sufficient time to spare and needs to be performed immediately before a time point at which the setting value such as the target power value is changed.

(i) Information of Frequency (Reciprocal of Cycle Time) or Cycle Time of Predetermined Period

(ii) Information of Target Power Value for Each Level

(iii) Information of Duty Ratio

For example, in a case where the amplitude modulation described with reference to FIGS. 9 and 10 is performed, the periods of No. 1 and No. 2 are set as predetermined periods, and it is necessary to transmit information of a total of five setting values of the following (A) to (C) from the external control device 101 to the high-frequency power source device 10 or 30 immediately before the period of No. 1 starts.

Note that the repeat counts of the periods of No. 1 and No. 2 are twice; however, since the repetition is automatically performed until information of a setting value for the next predetermined period is transmitted from the external control device 101 to the high-frequency power source device 10 or 30, it is not necessary to perform the transmission again at the time of the second repetition. Therefore, the total time including the repetition of the predetermined periods (periods of No. 1 and No. 2) is 400 μs.

(A) Frequency (Reciprocal of Cycle Time) or Cycle Time of Predetermined Period

5,000 Hz for Frequency and 200 μs for Cycle Time

(B) Information of Target Power Value

Target Power Value in Period of No. 1: 1,000 W

Target power value in Period of No. 2: 900 W

(C) Information of Duty Ratio

Time of Period of No. 1/(Time of Period of No. 1 + Time of Period of No. 2): 50%

Time of Period of No. 2/(Time of Period of No. 1 + Time of Period of No. 2): 50%

Next, with No. 3 and No. 4 as the predetermined periods (the repeat count: once), information of a total of five setting values needs to be transmitted from the external control device 101 to the high-frequency power source device 10 or 30 immediately before the period of No. 3 starts.

As described above, since a total time of the previous predetermined periods (the periods of No. 1 and No. 2) is 400 μs, it is necessary to transmit the information of the total of five setting values from the external control device 101 to the high-frequency power source device 10 or 30 within the time of 400 μs. However, in a current state of a technical level, it is difficult to complete the transmission in such a short time.

Next, with the periods of No. 5 and No. 6 as the predetermined periods (the repeat count: three times), it is necessary to transmit information of the setting values (information of a total of five setting values) from the external control device 101 to the high-frequency power source device 10 or 30 immediately before the period of No. 5 starts. However, since the total time of the previous predetermined periods (the periods of No. 3 and No. 4) is 400 μs, it is difficult to complete the transmission of the information of the setting values within this time.

Thereafter, the process proceeds in the order of the periods of No. 1 and No. 2 (the repeat count: twice) → the periods of No. 3 and No. 4 (the repeat count: once) → the periods of No. 5 and No. 6 (the repeat count: three times) → the periods of No. 7 and No. 8 (the repeat count: twice) → the periods of No. 9 and No. 10 (the repeat count: twice) → the periods of No. 7 and No. 8 (the repeat count: twice) → the periods of No. 9 and No. 10 (the repeat count: twice).

However, since the total time is short in any one of the periods, it is difficult to complete the transmission of the information of the setting value.

Therefore, in a case where the setting value information ST for the high-frequency power source device is not used, it is difficult to perform the amplitude modulation described with reference to FIGS. 9 and 10.

On the other hand, in a case where the setting value information ST for the high-frequency power source device is used, the high-frequency power source-dedicated setting value information ST1 and ST3 necessary for performing the amplitude modulation can be set in advance in the high-frequency power source devices 10 and 30, when the amplitude modulation is performed in the high-frequency power source devices 10 and 30. Therefore, it is possible to realize the amplitude modulation in which the setting value needs to be changed in a shorter time than the time required for transmitting the various setting values St from the external control device 101 to the high-frequency power source devices 10 and 30. For example, the complicated amplitude modulation described in FIGS. 9 and 10 can also be realized.

In recent years, there is a demand for a complicated amplitude modulation waveform. In addition, there is a demand for a change in the setting value such as the target power value at high speed. Even in such a case, as described above, since the use of the setting value information ST for the high-frequency power source device enables the setting value such as the target power value to be changed at high speed in the high-frequency power source device, effects obtained in the embodiment are very useful.

### Setting Value Information ST for Impedance Matcher

The impedance matcher performs impedance matching in accordance with an output state of the high-frequency power source device. Therefore, it is conceivable that the high-frequency power source device outputs, to the impedance matcher, an acquisition timing signal for identifying the period during which the load information is to be acquired.

However, as described above, depending on the communication status between the high-frequency power source device and the external control device in the high-frequency power source device, there may be a case where the process of the high-frequency power source device cannot be appropriately performed.

For example, the following (1) to (3) are conceivable.

(1) In a case where the target power value is changed from the external control device, the acquisition timing signal may be shifted.

(2) A signal line for transmitting the acquisition timing signal may be affected by noise and may malfunction.

(3) Depending on a surrounding environment such as an installation location of the high-frequency power source device and the impedance matcher, the signal line may not be connected.

In such a state, if the process of outputting, from the high-frequency power source device to the impedance matcher, the acquisition timing signal for identifying the period during which the load information is to be acquired is performed, an arithmetic load on the high-frequency power source device side is increased, and this is not preferable. However, when the impedance matcher uses the setting value information ST, the acquisition timing signal for identifying the period during which the load information is to be acquired does not need to be output from the high-frequency power source device to the impedance matcher.

Although the example in which the setting value information ST is used in both the high-frequency power source device and the impedance matcher has been described above, the high-frequency power source device may not use the setting value information ST, and the impedance matcher may use the setting value information ST.

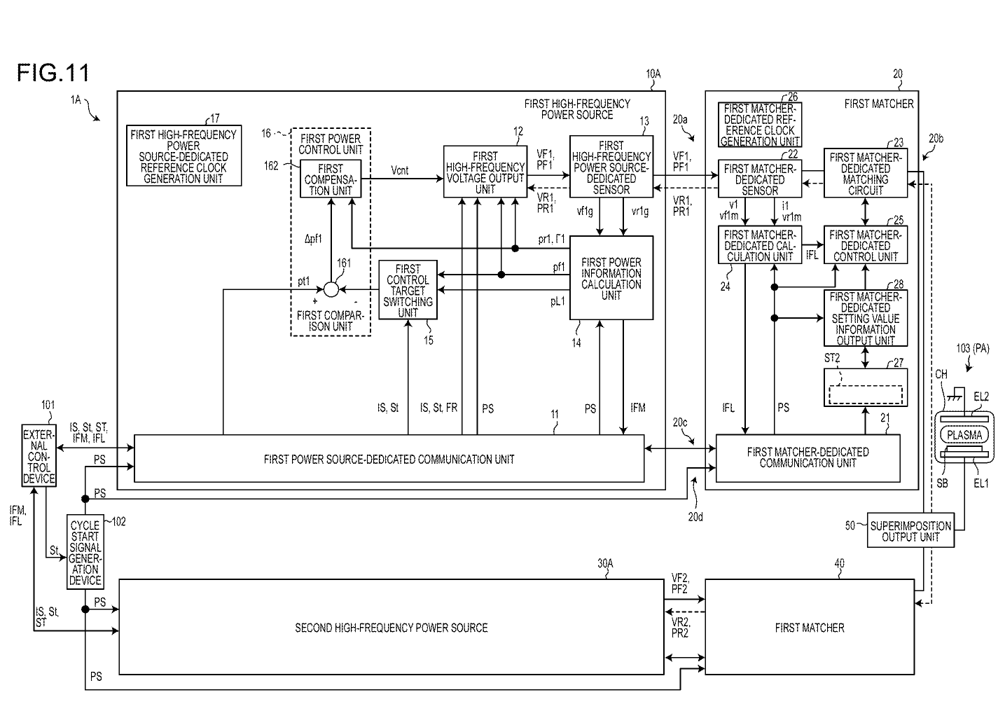

Note that, as a modification example of the embodiment, a high-frequency power supply system 1A may be configured as illustrated in FIG. 11. FIG. 11 is a diagram illustrating a configuration of the high-frequency power supply system 1A according to the modification example of the embodiment.

FIG. 11 illustrates an example in which the high-frequency power source device does not use the setting value information ST, and the impedance matcher uses the setting value information ST. In FIG. 11, the high-frequency power source devices are a first high-frequency power source 10A and a second high-frequency power source 30A, and the impedance matchers are the first matcher 20 and the second matcher 40.

Unlike the first high-frequency power source 10 illustrated in FIGS. 2A to 2E, the first high-frequency power source 10A illustrated in FIG. 11 does not include the first high-frequency power source-dedicated information storage unit 18, the first high-frequency power source-dedicated setting value information ST1, and the first high-frequency power source-dedicated setting value information output unit 19. Therefore, the first high-frequency power source 10A illustrated in FIG. 11 receives the target power value pt1 (one kind of various setting values St) output from the external control device 101 via the first high-frequency power source-dedicated communication unit 11 and outputs the received target power value pt1 toward the first comparison unit 161.

In addition, the first high-frequency power source 10A illustrated in FIG. 11 receives the command signal IS output from the external control device 101 via the first high-frequency power source-dedicated communication unit 11 and outputs the received command signal IS toward the first control target switching unit 15. Note that the command signal IS here is a signal for switching a control target, the signal being a kind of command signal IS. The first control target switching unit 15 determines a control target based on the command signal IS. This allows the forward wave power constant control or the load-side power constant control to be performed.

The first high-frequency power source 10A illustrated in FIG. 11 also receives the frequency information FR or the like (a type of various setting values St) from the external control device 101, as necessary. When the received information is the frequency information FR, for example, the frequency information is output toward the first high-frequency voltage output unit 12.

Other configurations of the first high-frequency power source 10A illustrated in FIG. 11 are similar to those of the first high-frequency power source 10 described in FIGS. 2A to 2E.

In addition, the second high-frequency power source 30A illustrated in FIG. 11 has the same basic functions as the first high-frequency power source 10A illustrated in FIG. 11, and thus the description thereof is omitted.

As described above, even in a case where the impedance matcher uses the setting value information ST, the high frequency power supply device does not necessarily need to use the setting value information ST.

### Supplementary note 1

An impedance matcher that is provided between a load and a high-frequency power source configured to supply a high-frequency voltage to the load, the impedance matcher including: a matching circuit that includes a variable element inside and is capable of changing impedance when

viewed from an input end of the impedance matcher; a matcher-dedicated setting value information output unit configured to output a matcher-dedicated setting value corresponding to an elapsed time from a start point of a cycle within a time of one cycle of amplitude modulation in a case where the high-frequency power source performs amplitude modulation control or a command signal corresponding to the matcher-dedicated setting value based on matcher-dedicated setting value information indicating a relationship between the matcher-dedicated setting value and the elapsed time; and a control unit configured to output a control signal to the matching circuit based on the matcher-dedicated setting value or the command signal output from the matcher-dedicated setting value information output unit, in which the matcher-dedicated setting value information output unit is configured to set, as the start point, a time point at which a cycle start signal that is a signal generated for each time of one cycle of the amplitude modulation and is common to the high-frequency power source is input or a time point obtained by adding a delay time to the time point at which the cycle start signal is input.

### Effects

In the present invention, the matcher-dedicated setting value corresponding to the elapsed time or the command signal corresponding to the matcher-dedicated setting value can be output based on the matcher-dedicated setting value information indicating the relationship between the elapsed time after the start point and the matcher-dedicated setting value, with the time point at which the cycle start signal generated for each time of one period of the amplitude modulation is input or the time point at which the delay time is added to the time point at which the cycle start signal is input are set as a start point of the cycle within the time of one period of the amplitude modulation.

Since the cycle start signal is common to the high- frequency power source, it is possible to perform control in accordance with pulse modulation of the high-frequency power source based on the matcher-dedicated setting value information. Therefore, it can be unnecessary to output an acquisition timing signal from the high-frequency power source to the impedance matcher.

### Supplementary note 2

The impedance matcher according to Supplementary note 1, in which the matcher-dedicated setting value includes a setting value of an acquisition period of load information about the load.

### Effects

When the high-frequency power source performs the amplitude modulation, it is possible to easily set the acquisition period of the load information in the impedance matcher.

### Supplementary note 3

The impedance matcher according to Supplementary note 1 or 2, in which the matcher-dedicated setting value information is reusable.

### Effects

When the matcher-dedicated setting value information is usable repeatedly, it is only necessary to set the matcher-dedicated setting value information in a relatively short time, so that the setting is simplified.

According to the impedance matcher of the present disclosure, it can be unnecessary to output an acquisition timing signal of load information from the high-frequency power source to the impedance matcher.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the

methods and systems described herein may be made without departing from the spirit of the inventions. The accompanying claims and their equivalents are intended to cover such forms or modifications as would fall within the scope and spirit of the inventions.

What is claimed is:

1. An impedance matcher comprising:
an input end connectable to a high-frequency power source configured to supply high-frequency power;
an output end connectable to a load;
a matching circuit that includes a variable element inside and is capable of changing impedance when viewed from the input end;
a matcher-dedicated setting value information output circuit configured to output a matcher-dedicated setting value corresponding to an elapsed time from a start point of a cycle within a time of one cycle of amplitude modulation in a case where the high-frequency power source performs amplitude modulation control or a command signal corresponding to the matcher-dedicated setting value based on matcher-dedicated setting value information indicating a relationship between the elapsed time and the matcher-dedicated setting value; and
a control circuit configured to output a control signal to the matching circuit based on the matcher-dedicated setting value or the command signal output from the matcher-dedicated setting value information output circuit,
wherein the matcher-dedicated setting value information output circuit is configured to set, as the start point, a time point at which a cycle start signal that is a signal generated for each time of one cycle of the amplitude modulation and is common to the high-frequency power source is input or a time point obtained by adding a delay time to the time point at which the cycle start signal is input.

2. The impedance matcher according to claim 1,
wherein the matcher-dedicated setting value includes a setting value of an acquisition period of load information about the load.

3. The impedance matcher according to claim 1,
wherein the matcher-dedicated setting value information is reusable.
